(19) United States
(12) Patent Application Publication
(10) Pub. No.: US 2020/0156323 A1
(43) Pub. Date: May 21, 2020

(54) SYSTEMS AND METHODS FOR OPTIMIZATION OF DESIGN AND TOOL PATHS FOR ADDITIVE MANUFACTURING

(71) Applicant: Arevo, Inc., Milpitas, CA (US)

(72) Inventors: Peter John Woytowitz, Los Altos, CA (US); Dantong He, Cupertino, CA (US); Sohil Nandu, San Francisco, CA (US); Sushrut Pavanaskar, Castro Valley, CA (US); Juraj Vanek, Sunnyvale, CA (US)

(21) Appl. No.: 16/688,316

(22) Filed: Nov. 19, 2019

Related U.S. Application Data
(60) Provisional application No. 62/770,043, filed on Nov. 20, 2018.

(51) Int. Cl. B29C 64/393; G06F 30/23; G06T 17/20; B33Y 10/00; B33Y 50/02

(52) U.S. Cl. CPC B29C 64/393; G06F 30/23; B33Y 50/02; B33Y 10/00; G06T 17/20

(57) ABSTRACT

The present disclosure provides methods for printing a three-dimensional (3D) object, comprising processing a computer model of the 3D object to generate a strength or stress profile of the computer model. Next at least (i) the strength or stress profile from processing the computer model and (ii) a topology of the 3D object may be used to generate a tool path for printing the 3D object. Printing of the 3D object may be simulated using the tool path to yield a simulated 3D object. The simulated 3D object may be analyzed to determine whether the simulated 3D object meets a threshold. If the simulated 3D object meets the threshold, printing instructions comprising the tool path may be generated for use by a 3D printer to print the 3D object.

### CROSS-REFERENCE

This application claims priority to U.S. Provisional Application No. 62/770,043 filed on Nov. 20, 2018, which is entirely incorporated herein by reference.

### BACKGROUND

Additive manufacturing (AM) can be a process of creating three-dimensional parts by depositing overlapping layers of material under the guided control of a computer. Techniques of additive manufacturing can include, without limitation, fused deposition modeling (FDM), fused filament fabrication (FFF), Plastic Jet Printing (PJP), stereolithography (SLA), selective laser sintering (SLS), selective laser melting (SLM), and material jetting (MJ). Using AM technique(s), a material (e.g., a heated and/or pressurized thermoplastic) can pass through a print head, and the print head can be moved in a predefined trajectory (e.g., a tool path) as the material discharges from the print head, such that the material can be laid down in a particular pattern and shape of overlapping layers. The material, after exiting the print head, can harden into a final form.

Although AM has developed for over three decades to include many different processes and materials, the adoption of AM in industrial manufacturing has been limited, possibly because it can be significantly different from the traditional subtractive manufacturing processes which dominated manufacturing in the past.

### SUMMARY

Additive manufacturing processes for composite materials may offer new opportunities for optimizing designs through precise fiber orientation and infill density specification. Such optimization can advantageously lead to significant weight savings along with reduced material costs and build times.

Additive manufacturing processes can be characterized by repeated deposition of thin layers of plastic or metal to result in a 3-dimensional (3D) part. Using various AM technologies (e.g. fused deposition, laser sintering, stereolithography), it may be possible to manufacture parts with different materials (e.g., plastics, metals, composite materials, and biological tissue). However, compared to traditional subtractive manufacturing processes, AM processes can be newer, not-well studied, and may require different assistive software tools.

In additive manufacturing, composites made using discontinuous fiber (e.g., using filament deposition methods) and continuous fiber (e.g., using directed energy deposition) may provide for flexibility in fiber orientation. Residual stresses can lead to reduced static load capacity, part warpage and can reduce fatigue life of components. Thus, determination of the optimal fiber orientation may require structural analysis, which may include design requirements for the object to be printed (e.g. maximum stress or deflection), and/or any types of process induced behavior (e.g. residual stresses). Additionally, the tool path of a print head may be influenced by the optimization of robot motion profiles and the effects of process physics including residual stress and the potential for part warpage. To capture such different considerations, the present disclosure includes systems and methods for simultaneous optimization of design and tool path for additive manufacturing. The present disclosure also includes an integrated computer aided design, engineering, and manufacturing software tool for design optimization, finite element analysis (FEA), toolpath generation and virtual 3D print simulation using additive manufacturing.

An aspect of the present disclosure provides a method (e.g., computer-implemented) for printing a three-dimensional (3D) object, comprising: (a) processing a computer model of the 3D object to generate a strength or stress profile of the computer model; (b) using at least (i) the strength or stress profile from (a) and (ii) a topology of the 3D object to generate a tool path for printing the 3D object; (c) simulating printing of the 3D object using the tool path to yield a simulated 3D object; (d) analyzing the simulated 3D object to determine whether the simulated 3D object meets a threshold; and (e) if the simulated 3D object meets the threshold, generating printing instructions comprising the tool path for use by a 3D printer to print the 3D object. In some embodiments, processing the computer model of the 3D object may comprise using finite element analysis (FEA) to generate the strength or stress profile. The method of printing the 3D object may further comprise, subsequent to (a) and prior to (b), using the computer model and the strength or stress profile to obtain the topology of the 3D object. In some embodiments, obtaining the topology may comprise performing topology optimization. The topology may be optimized by using a solid isotropic material with penalization algorithm. The topology may be obtained on an isotropic or anisotropic 3D object corresponding to the 3D object from the computer model. The topology may comprise solid and void regions. The topology may comprise only solid and void regions. The topology may comprise regions that are not solid or void. The topology may comprise regions of various densities. In some embodiments, using at least (i) the strength or stress profile from (a) and (ii) a topology of the 3D object may comprises: (1) generating an initial tool path; and (2) adjusting the initial tool path based on geometric parameters and/or fiber orientation to yield the 3D printer tool path. The geometric parameters may comprise one or more of: a raster angle of a layer, an infill density, a layer orientation, a perimeter thickness, and a thickness of layer. In some embodiments, the topology remains unaltered in (2). In some embodiments, (2) may comprise using additive finite element analysis. In some embodiments, (2) can be based at least in part on adjusting strain-energy density across a plurality of regions of the 3D object. The strain-energy density across a plurality of regions of the 3D object can be substantially uniform. The method of printing a 3D object may further comprise adjusting the strain-energy density across the plurality of regions until a stopping criterion is met, to yield substantial uniformity in the strain-energy density across the plurality of regions. In some embodiments, using at least (i) the strength or stress profile from (a) and (ii) a topology of the 3D object may further comprise optimizing fiber orientation based on the strength or stress profile, the topology, and/or geometric parameters to generate an optimized fiber orientation. In some embodiments, (2) may be further based on the optimized fiber orientation. The threshold can be a quality threshold. The computer model may comprise a computer-aided design or drafting data of the 3D object. The strength or stress profile may comprise information based on an estimated or predicted stress, calculated or predetermined strength of material for printing the 3D object, or both. The strength or stress profile herein may comprise comparing the predicted stress to the measured strength of the material for printing the 3D object. The strength or stress profile herein may comprise a comparing the predicted or estimated stress to a calculated strength of the material. If the strength exceeds the predicted or estimated stress, then, this particular threshold can be acceptable. Ratios of the strength to stress (i.e., Factor of Safety) can also be used and values (>1) can be used as acceptable indicator of the strength or stress profile in different types of industry. The strength or stress profile may be replaced with other criteria used in assessing structural performance, for example, a “stiffness” requirement, where one may require achieving some level of displacement. The printing instructions may comprise machine code to drive the 3D printer based on the tool path. Two or more among (a)-(e) may be performed automatically without involvement of a user. Two or more of (a)-(e) may comprise data in a common format. In some embodiments, processing a computer model of the 3D object may further comprise processing design specifications of the 3D object. The design specification may comprise a load and/or a boundary condition. In some embodiments, processing a computer model of the 3D object may comprise generating a 3D orthotropic stress-strain matrix for a plurality of elements of the 3D object. In some embodiments, processing a computer model of the 3D object may further comprise sampling the 3D orthotropic stress-strain matrix at integration points. In some embodiments, using at least (i) the strength or stress profile from (a) and (ii) a topology of the 3D object may further comprise separating the 3D object into laminates and determining strengths of laminates based on allowable stresses of the 3D object. In some embodiments, processing a computer model of the 3D object may comprise: i. analyzing an initial finite element mesh representing the 3D object with loads and/or boundary conditions, wherein a normalized element density may be one for a plurality of elements; ii. performing finite element analysis and calculating an element strain-energy density for the plurality of elements; iii. adjusting the normalized element density for the plurality of elements based on the element strain-energy density; and iv. repeating ii.-iii. until a stopping criterion may be met. In some embodiments, ii. may comprise using heuristic optimization to calculate the element strain-energy density and eliminating material in areas where the element strain-energy density may be low and increasing material density in areas where the element strain-energy density may be high. In some embodiments, analyzing the simulated 3D object may comprise determining whether the simulated 3D object includes one or more defects selected from the group consisting of: overlapping tool paths, overhanging paths, and collision of the 3D printer with an unfinished portion of the 3D object. In some embodiments, analyzing the simulated 3D object may comprise presenting the simulated 3D object and/or a simulation of the 3D printing of the 3D object on a user interface. The method of printing the 3D object may further comprise receiving the threshold from the user. The method of printing the 3D object may further comprise using the 3D printer to print the 3D object using the printing instructions.

In another aspect, the present disclosure provides a system (e.g., computer-implemented system) for printing a three-dimensional (3D) object, comprising: computer memory configured to store printing instructions comprising a tool path for use by a 3D printer to print the 3D object; and one or more computer processors operatively coupled to the computer memory, wherein the one or more computer processors can be individually or collectively programmed to: (a) process a computer model of the 3D object to generate a strength or stress profile of the computer model; (b) use at least (i) the strength or stress profile from (a) and (ii) a topology of the 3D object to generate the tool path for printing the 3D object; (c) simulate printing of the 3D object using the tool path to yield a simulated 3D object; (d) analyze the simulated 3D object to determine whether the simulated 3D object meets a threshold; and (e) if the simulated 3D object meets the threshold, generate the printing instructions comprising the tool path for use by the 3D printer to print the 3D object. In some embodiments, in (a), the one or more computer processors can be individually or collectively programmed to use finite element analysis (FEA) to generate the strength or stress profile. In some embodiments, the one or more computer processors can be individually or collectively programmed to, subsequent to (a) and prior to (b), use the computer model and the strength or stress profile to obtain the topology of the 3D object. In some embodiments, the one or more computer processors can be individually or collectively programmed to obtain the topology and further to perform topology optimization. In some embodiments, the one or more computer processors can be individually or collectively programmed to optimize the topology by using a solid isotropic material with penalization algorithm. In some embodiments, the one or more computer processors can be individually or collectively programmed to obtain topology on an isotropic or anisotropic 3D object corresponding to the 3D object from the computer model. The topology may comprise solid and void regions. The topology may comprise only solid and void regions. The topology may comprise regions that are not solid or void. The topology may comprise regions of various densities. In some embodiments, the one or more computer processors can be individually or collectively programmed to, in (b), (1) generate an initial tool path; and (2) adjust the initial tool path based on geometric parameters and/or fiber orientation to yield the 3D printer tool path. The geometric parameters may comprise one or more of: a raster angle of a layer, an infill density, a layer orientation, a perimeter thickness, and a thickness of layer. In some embodiments, the one or more computer processors can be individually or collectively programmed to unalter the topology in (2). In some embodiments, the one or more computer processors can be individually or collectively programmed to, in (2), use additive finite element analysis. In some embodiments, the one or more computer processors can be individually or collectively programmed to base (2) at least in part on adjusting strain-energy density across a plurality of regions of the 3D object. The strain-energy density across a plurality of regions of the 3D object can be substantially uniform. In some embodiments, the one or more computer processors can be individually or collectively programmed to further adjust the strain-energy density across the plurality of regions until a stopping criterion is met, to yield substantial uniformity in the strain-energy density across the plurality of regions. In some embodiments, the one or more computer processors can be individually or collectively programmed to, in (b), optimize fiber orientation based on the strength or stress profile, the topology, and/or geometric parameters to generate an optimized fiber orientation. In some embodiments, the one or more computer processors can be individually or collectively programmed to base (2) on the optimized fiber orientation. The threshold can be a quality threshold. The computer model may comprise a computer-aided design or drafting data of the 3D object. The strength or stress profile may comprise information based on an estimated or predicted stress, calculated or predetermined strength of material for printing the 3D object, or both. The strength or stress profile herein may comprise a comparison of the predicted stress and the measured strength of the material for printing the 3D object. The strength or stress profile herein may comprise a comparison of a predicted or estimated stress to a calculated strength of the material. If the calculated strength exceeds the predicted or estimated stress, then, this particular threshold can be acceptable. Ratios of the strength to stress (i.e., Factor of Safety) can also be used and values (>1) can be used as acceptable indicator of the strength or stress profile in different types of industry. The strength or stress profile may be replaced with other criteria used in assessing structural performance, for example, a “stiffness” requirement, where one may require achieving some level of displacement. The printing instructions may comprise machine code to drive the 3D printer based on the tool path. In some embodiments, the one or more computer processors can be individually or collectively programmed to perform two or more among (a)-(e) automatically without involvement of a user. Two or more of (a)-(e) may comprise data in a common format. In some embodiments, the one or more computer processors can be individually or collectively programmed to, in (a), further process design specifications of the 3D object, the design specification may comprise a load and/or a boundary condition. In some embodiments, the one or more computer processors can be individually or collectively programmed to, in (a), generate a 3D orthotropic stress-strain matrix for a plurality of elements of the 3D object. In some embodiments, the one or more computer processors can be individually or collectively programmed to, in (a), sample the 3D orthotropic stress-strain matrix at integration points. In some embodiments, the one or more computer processors can be individually or collectively programmed to, in (b), separate the 3D object into laminates and determine strengths of laminates based on allowable stresses of the 3D object. In some embodiments, the one or more computer processors can be individually or collectively programmed to, in (a), i. analyze an initial finite element mesh representing the 3D object with loads and/or boundary conditions, wherein a normalized element density may be one for a plurality of elements; ii. perform finite element analysis and calculating an element strain-energy density for the plurality of elements; iii. adjust the normalized element density for the plurality of elements based on the element strain-energy density; and iv. repeat ii.-iii. until a stopping criterion may be met. In some embodiments, the one or more computer processors can be individually or collectively programmed to, in ii., use heuristic optimization to calculate the element strain-energy density and eliminating material in areas where the element strain-energy density may be low and increasing material density in areas where the element strain-energy density may be high. In some embodiments, the one or more computer processors can be individually or collectively programmed to, in (d), determine whether the simulated 3D object includes one or more defects selected from the group consisting of: overlapping tool paths, overhanging paths, and collision of the 3D printer with an unfinished portion of the 3D object. In some embodiments, the one or more computer processors can be individually or collectively programmed to, in (d), present the simulated 3D object and/or a simulation of the 3D printing of the 3D object on a user interface. In some embodiments, the one or more computer processors can be individually or collectively programmed to receive the threshold from the user. In some embodiments, the one or more computer processors can be individually or collectively programmed to use the 3D printer to print the 3D object using the printing instructions.

In another aspect, a method is provided for printing a three-dimensional (3D) object. The method comprises: (a) processing a computer model of the 3D object to generate a topology of the 3D object, wherein the topology is generated based at least in part on a first structural analysis; (b) using the first structural analysis and the topology to generate a tool path for printing the 3D object; and (c) using a second structural analysis to adjust one or more geometric parameters or a fiber direction of the tool path, to provide an updated tool path that is usable to print the 3D object.

In some embodiments, the first structural analysis comprises use of finite element analysis (FEA) that generates a strength or stress profile of the computer model. In some embodiments, the tool path is a 3D tool path. In some embodiments, the second structural analysis comprises use of an additive finite element analysis.

In some embodiments, the method further comprises simulating printing of the 3D object using the updated tool path to generate a simulated 3D object. In some cases, the method further comprises analyzing the simulated 3D object to determine whether the simulated 3D object meets a threshold corresponding to the 3D object, and if the simulated 3D object meets the threshold, generating printing instructions comprising the updated tool path for use by a 3D printer to print the 3D object. In some embodiments, the one or more geometric parameters comprise one or more members selected from the group consisting of a raster angle of a layer, an infill density, a layer orientation, a perimeter thickness, and a thickness of layer.

Another aspect of the present disclosure provides a non-transitory computer readable medium comprising machine executable code that, upon execution by one or more computer processors, implements any of the methods above or elsewhere herein.

Another aspect of the present disclosure provides a system comprising one or more computer processors and computer memory coupled thereto. The computer memory comprises machine executable code that, upon execution by the one or more computer processors, implements any of the methods above or elsewhere herein.

Consistent with other disclosed embodiments, non-transitory computer-readable storage media can store program instructions, which can be executed by a processor to perform any of the methods described herein.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings (also “Figure” and “FIG.” herein), of which:

FIG. 1 schematically illustrates a flow chart for simultaneous optimization of design and tool path for printing a 3D object;

FIG. 2 schematically illustrates a process for determining the strength profile of a 3D object based on the maximum stress criteria using a laminate strength approach;

FIG. 3 schematically illustrates a process flow for initial topology optimization;

FIG. 4 schematically illustrates a process flow for tool path determination using additive finite element analysis;

FIGS. 5A-5D show structural analysis and optimization of a box beam using the systems and methods herein;

FIGS. 6A-6F show structural analysis and optimization of a truss using the systems and methods herein;

FIGS. 7A-7B show a computer model of a 3D object with walls reinforced as a result of FEA analysis (FIG. 7A) and resulting toolpaths (FIG. 7B) generated using the systems and methods herein;

FIGS. 8A-8B show a computer model of a 3D non-planar object (FIG. 8A) and the generated full-3D toolpath (FIG. 8B);

FIGS. 9A-9B show a visualization of progressive printing of toolpaths and machine code using a 3D printer simulator;

FIGS. 10A-10D show a visualization of overhangs, overlaps and collisions (FIG. 10A), tool speed (FIG. 10B), layers with filament directions (FIG. 10C), and machine code categories (FIG. 10D) in simulated printing of 3D objects using a 3D printer simulator;

FIGS. 11A-11F show a 3D part (FIG. 11A) undergoing finite element analysis. Boundary conditions and forces may be added (FIG. 11B) and solved using FEA (FIG. 11C). Based on the results from FEA analysis, a strength-driven toolpath and machine code for the tool paths can be generated (FIG. 11D). Machine code may be visualized and checked by a virtual printer (FIG. 11E). The surface extraction during the simulation can be compared with the original model to check for any deviations from the original shape (FIG. 11F);

FIGS. 12A-12C show alignment of fibers (discontinuous fibers) (FIGS. 12B-12C) printed using fused filament fabrication (FDM) (FIG. 12A);

FIGS. 13A-13C show examples of sparse infill patterns using the systems and methods herein; and

FIG. 14 shows a computer control system that is programmed or otherwise configured to implement methods provided herein.

### DETAILED DESCRIPTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed.

The term “three-dimensional printing” (also “3D printing”), as used herein, generally refers to a process or method for generating a 3D part (or object). For example, 3D printing may refer to sequential addition of material layer or joining of material layers or parts of material layers to form a three-dimensional (3D) part or structure, in a controlled manner (e.g., under automated control). In the 3D printing process, the deposited material can be fused, sintered, melted, bound or otherwise connected to form at least a part of the 3D object. Fusing the material may include melting or sintering the material. Binding can comprise chemical bonding. Chemical bonding can comprise covalent bonding. Examples of 3D printing include additive printing (e.g., layer by layer printing, or additive manufacturing). The 3D printing may further comprise subtractive printing.

The term “part,” as used herein, generally refers to an object, e.g., 3D object to be printed. A part may be generated using 3D printing methods and systems of the present disclosure. A part may be a portion of a larger part or object, or an entirety of an object. A part may have various form factors, as may be based on a model of such part. Such form factors may be predetermined.

Whenever the term “at least,” “greater than,” or “greater than or equal to” precedes the first numerical value in a series of two or more numerical values, the term “at least,” “greater than” or “greater than or equal to” applies to each of the numerical values in that series of numerical values. For example, greater than or equal to 1, 2, or 3 is equivalent to greater than or equal to 1, greater than or equal to 2, or greater than or equal to 3.

Whenever the term “no more than,” “less than,” or “less than or equal to” precedes the first numerical value in a series of two or more numerical values, the term “no more than,” “less than,” or “less than or equal to” applies to each of the numerical values in that series of numerical values. For example, less than or equal to 3, 2, or 1 is equivalent to less than or equal to 3, less than or equal to 2, or less than or equal to 1.

Examples of 3D printing methodologies comprise extrusion, wire, granular, laminated, light polymerization, or power bed and inkjet head 3D printing. Extrusion 3D printing can comprise robo-casting, fused deposition modeling (FDM) or fused filament fabrication (FFF). In some cases, the 3D printing may be performed without extrusion. For example, beads may be deposited (e.g., in FFF) in a manner that does not involve extrusion. Wire 3D printing can comprise electron beam freeform fabrication (EBF3). Granular 3D printing can comprise direct metal laser sintering (DMLS), electron beam melting (EBM), selective laser melting (SLM), selective heat sintering (SHS), or selective laser sintering (SLS). Power bed and inkjet head 3D printing can comprise plaster-based 3D printing (PP). Laminated 3D printing can comprise laminated object manufacturing (LOM). Light polymerized 3D printing can comprise stereo-lithography (SLA), digital light processing (DLP) or laminated object manufacturing (LOM).

3D printing may be performed using various materials. In some examples, a material that may be used in 3D printing includes a polymeric material, elemental metal, metal alloy, a ceramic, an allotrope of elemental carbon, or a combination thereof. The allotrope of elemental carbon may comprise amorphous carbon, graphite, graphene, diamond, or fullerene. The fullerene may be selected from the group consisting of a spherical, elliptical, linear, and tubular fullerene. The fullerene may comprise a buckyball or a carbon nanotube. The material may comprise an organic material, for example, a polymer or a resin. The material may comprise a solid or a liquid. The solid material may comprise powder material. The powder material may be coated by a coating (e.g., organic coating such as the organic material (e.g., plastic coating)). The powder material may comprise sand. The material may be in the form of a powder, wire, pellet, or bead. The material may have one or more layers. The material may comprise at least two materials. In some cases, the material includes a reinforcing material (e.g., that forms a fiber). The reinforcing material may comprise a carbon fiber, Kevlar®, Twaron®, ultra-high-molecular-weight polyethylene, or glass fiber.

In an aspect, the present disclosure provides a method for printing a 3D object. The method may comprise processing a computer model of the 3D object to generate a strength or stress profile of the computer model. Next, at least (i) the strength or stress profile from the processing and (ii) a topology of the 3D object may be used to generate a 3D printer tool path for printing the 3D object. The printing of the 3D object may be simulated using the 3D printer tool path to yield a simulated 3D object. The simulated 3D object may be analyzed to determine whether the simulated 3D object meets a threshold. If the simulated 3D object meets the threshold, printing instructions may be generated comprising the 3D printer tool path for use by a 3D printer to print the 3D object. In some cases, two or more among processing a computer model of the 3D object, generation of the 3D printer tool path, simulation of printing the 3D object, analysis of the simulated 3D object, and generation of printing instructions may be performed automatically without involvement of a user. In other cases, two or more of processing a computer model of the 3D object, generation of the 3D printer tool path, simulation of printing the 3D object, analysis of the simulated 3D object, and generation of printing instructions may comprise data in a common format.

In some cases, the processing a computer model of the 3D object comprises using finite element analysis (FEA) to generate the strength or the stress profile. In other cases, the method for printing the 3D object further comprises, subsequent to processing a computer model and prior to generation of the 3D printer tool path, the computer model and the strength or the stress profile may be used to obtain the topology of the 3D object. Obtaining the topology may comprise performing topology optimization. The topology can be optimized by using a solid isotropic material with penalization algorithm. In some cases, the topology may be obtained on an isotropic or anisotropic 3D object corresponding to the 3D object from the computer model. The topology may comprise solid and void regions. In some cases, the topology can comprise only solid and void regions. In other cases, the topology may comprise regions that are not solid or void. The topology can comprise regions of various densities.

In some cases, generation of a 3D printer tool path may comprise (1) generating an initial tool path; and (2) adjusting the initial tool path based on geometric parameters and/or fiber orientation to yield the 3D printer tool path. The geometric parameters may comprise one or more elements selected from the group consisting of a raster angle of a layer, an infill density, a layer orientation, a perimeter thickness, and a thickness of layer. The topology can remain unaltered in (2). In some cases, (2) comprises using additive finite element analysis. In other cases, (2) may be based at least in part on adjusting strain-energy density across a plurality of regions of the 3D object. The strain-energy density across a plurality of regions of the 3D object may be uniform. The method for printing a 3D object may further comprise adjusting the strain-energy density across the plurality of regions until a stopping criterion is met, to yield substantial uniformity in the strain-energy density across the plurality of regions. Generation of a 3D printer tool path may further comprise optimizing fiber orientation based on the strength or the stress profile, the topology, and/or geometric parameters to generate an optimized fiber orientation. In some cases, (2) may be further based on the optimized fiber orientation.

In some cases, the threshold may be a quality threshold. The computer model can comprise CAD data of the 3D object. In other cases, the strength or the stress profile can comprise information based on estimated or predicted stress, predetermined or calculated material strength, or both. In some cases, the printing instructions can comprise machine code to drive the 3D printer based on the 3D printer tool path.

In some cases, processing the computer model of the 3D object further comprises processing the design specifications of the 3D object. The design specifications may comprise a load and/or a boundary condition. In other cases, processing the computer model of the 3D object may comprise generating a 3D orthotropic stress-strain matrix for a plurality of elements of the 3D object. Processing the computer model of the 3D object may further comprise sampling the 3D orthotropic stress-strain matrix at integration points. Generation of a 3D printer tool path may further comprise separating the 3D object into laminates and determining strengths of laminates based on allowable stresses of the 3D object.

In some cases, processing the computer model of the 3D object may comprise i. analyzing an initial finite element mesh representing the 3D object with loads and/or boundary conditions, wherein a normalized element density is one for a plurality of elements; ii. performing finite element analysis and calculating an element strain-energy density for the plurality of elements; iii. adjusting the normalized element density for the plurality of elements based on the element strain-energy density; and iv. repeating ii.-iii. until a stopping criterion is met. In some cases, ii. may comprise using heuristic optimization to calculate the element strain-energy density and eliminating material in areas where the element strain-energy density is low and increasing material density in areas where the element strain-energy density is high.

In some cases, analyzing the simulated 3D object may comprise determining whether the simulated 3D object includes one or more defects selected from the group consisting of overlapping tool paths, overhanging paths, and collision of the 3D printer with a unfinished portion of the 3D object. In other cases, analyzing the simulated 3D object can comprise presenting the simulated 3D object and/or a simulation of the print of the 3D object on a user interface. In some cases, presenting the simulated 3D object and/or a simulation of the print of the 3D object further comprises receiving the threshold from the user.

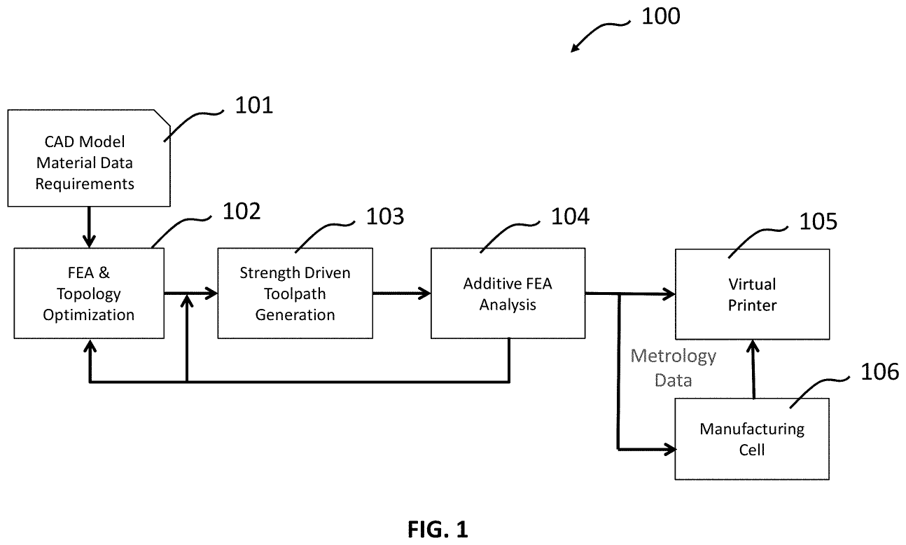

FIG. 1 shows a process flow 100 for simultaneous optimization of design and tool path. Such process flow or one or more operations in the process flow may be used in but not limited to a computer algorithm, a software module, a web or mobile application, or the like. Referring to FIG. 1, an input model (e.g. 3D model) can be loaded into the methods or systems disclosed herein. Such input model may be of a common format (e.g. STL, OBJ or STEP files). Material properties can be applied to the input model, in some cases, from the pre-created material library with multiple materials 101.

Next, an initial finite element analysis and topology optimization 102 may be performed. Finite element analysis (FEA) can be used to calculate the structural strength of the input model and the results of the FEA may be further used to optimize the topology of the input model.

For the structural analysis, FEA methods, such as the standard h-method finite element method may be used. In some cases, the standard h-method may be used for developing element stiffness matrices and element load vectors that can then be globally assembled. In other cases, the h-method may refer to decreasing the characteristic length (h) of elements by dividing each existing element into two or more elements without changing the type of elements used. In the following system of linear equations, equation 1 determines the vector of nodal loads F using

K d=F Equation 1

global stiffness matrix K and the vector of nodal displacements d. The assembly and solution can be found using FEA. However, in developing the element stiffness matrices K^{(e)} and the element thermal load vectors F_{θ}^{(e)} using the equations 2 and 3,

$$\begin{matrix}{K}^{( e )} = {\int }_{V} {B}^{T} DB dV & Equation 2 \\ {F}_{θ}^{( e )} = {\int }_{V} {B}^{T} D {ɛ}_{th} dV & Equation 3\end{matrix}$$

In equations 2 and 3, appropriate matrices D may be determined with care using B is the strain-displacement matrix, cₜh is the thermal strain vector, and D is the 3D orthotropic stress-strain matrix.

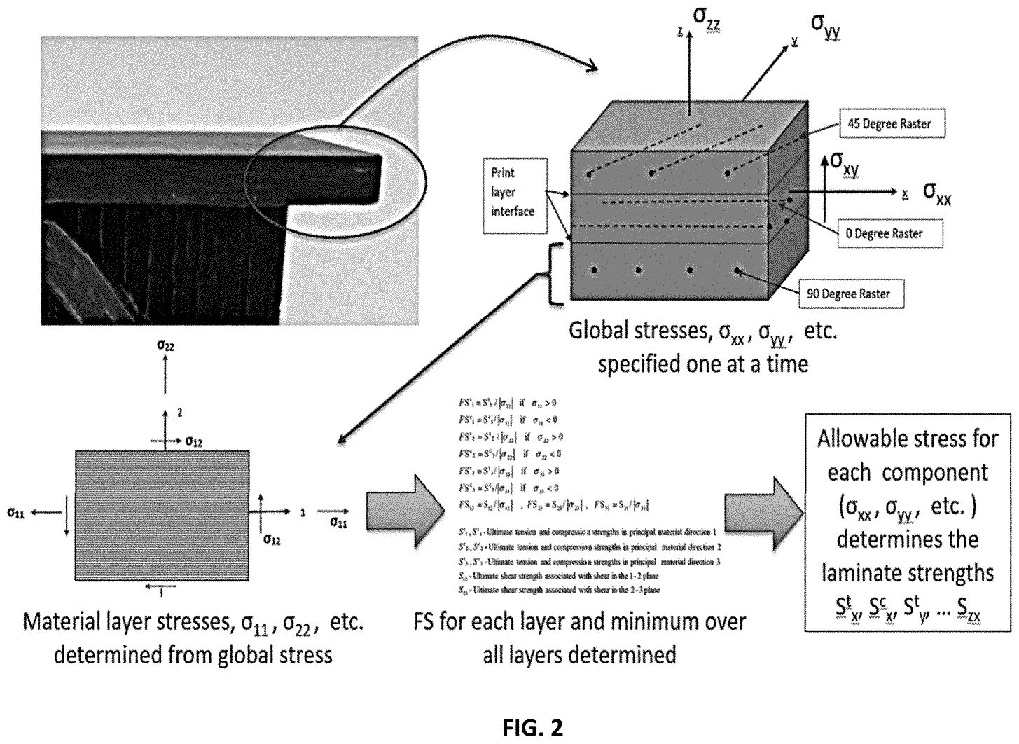

The structural analysis provided by the present disclosure may be suitable for analyzing complex structures or complex material and mechanical properties. For instance, the stress-strain property may vary across different elements (e.g., elements in FEA) based on the fiber orientations. For example, for 3D printed structures that are designed to optimize fiber directions, the D matrix may vary per element. The D matrix and the element-wise variation may be obtained using different approaches. In some embodiments, the D matrix may be using a continuum approach, a laminate approach or a combination of both. The continuum approach may utilize the tool path data, such as G-code. The stress-strain matrix may be obtained by sampling at selected locations of the elements. For example, when integration is performed, the stress-strain matrices (e.g., D matrices) may be sampled at the integration points or Gaussian points. Such sampling can be equivalent to homogenization. The laminate approach may be applied when a structure of the 3D object has a characteristic dimension (e.g. thickness) that is similar to or about the same size of the element in which case the continuum approach may not be accurate. Accurate stress prediction in composite laminates may be crucial for safe design under different loading conditions. Classical lamination theory may be used to analyze the behavior of laminated composite to evaluate stresses and strains in individual plies in the laminate. By applying the lamination theory in 3D, strength may be calculated based on the maximum stress criteria as depicted in FIG. 2.

FIG. 2 illustrates a method of calculating a laminate strength. Referring to FIG. 2, material layer stresses may be determined from the global stress of the object. Factor of Safety (FS) value for each layer and the minimum FS value for all material layers are determined. Based on the FS values, the overall strength of the laminate may be assessed. This may be done in various ways depending upon the application. For example, in some applications material matrix failure may be of concern, while, in other applications only failure of the material fibers may be of concern. The above-mentioned structural analysis or one or more steps of the above-mentioned structural analysis method may be performed throughout the simultaneous design and optimization process flow.

Referring to FIG. 1, the initial topology optimization operation may involve using material interpolation methods, such as the standard Sequential Isotropic Material with Penalization (SIMP). and a topology optimization method. The topology optimization method may be a heuristic optimization method based on element strain-energy density, U(e). In some cases, using the SIMP method, the stiffness of intermediate density elements (i.e. elements with normalized element density, ρₑ, such that 0<ρₑ<1) may be penalized to achieve a design goal such as weight reduction. The topology optimization method may adopt any suitable constraints (e.g., maximum stress values, a pre-determined topology) for updating/optimizing towards the design goal. In some cases, with a predetermined topology such as a “black and white” topology, namely one containing solid (black) and void (white) regions only, the heuristic optimization method may calculate the strain-energy density on an element-by-element basis (e.g., elements in FEA) and based on the strain-energy density, the material in areas where the strain-energy density is low (e.g., lower than a determined threshold) may be eliminated, and material can be increased in regions where strain-energy density is high. The problems variables (e.g., material density) may be in part based on the material interpolation method. For example, the SIMP method may perform sequential finite element analyses while updating individual element strain-energy densities. In contrast to the “black and white” topology, a variable strain-energy density may be obtained by using a different the material interpolation scheme. For instance, in the areas or regions where the strain-energy density is low (e.g., below a pre-determined threshold), the material density may be reduced.

The design goal for the initial topology optimization may be a weight reduction goal or quantity minimization. In some cases, when the percentage weight reduction is high, then more aggressive designs may be achieved, compared to designs with lower weight reductions. After the initial topology optimization, the 3D model of the input model may be updated and to represent the new topology.

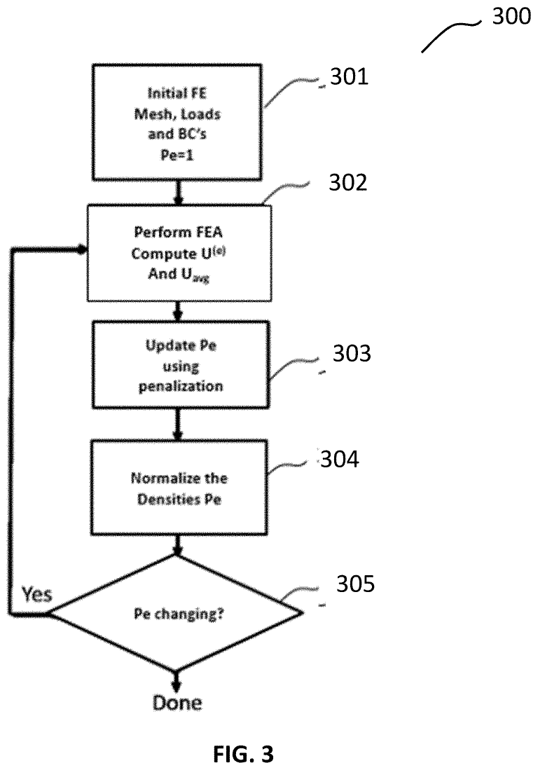

FIG. 3 shows an example process flow 300 for initial topology optimization. The methods or systems for initial topology optimization may use FEA. Initial finite element mesh may be analyzed with specified loads and boundary conditions and with an initial element strain-energy density as solid and normalized densities at operation 301 (e.g., ρₑ=1 for elements e=1, . . . , Nₑₗ). Next, in operation 302, the element strain-energy density, U^{(e)}, may be calculated using FEA and/or heuristic optimization. The average strain-energy density U_{avg} can also be calculated at operation 302. In operation 303 the ρₑ may be updated using penalization. For example, strain-energy density ρₑ can be increased in elements if U^{(e)} exceeds the average U_{avg} value or decreased if U^{(e)} is below average U_{avg} value. U^{(e)} at any location inside the input model representing the object to be printed may be determined using equations 4 and 5:

$$\begin{matrix}U = ( \frac{1}{2} ) {σ}^{T} ( x , y , z ) ɛ ( x , y , z ) = ( \frac{1}{2} ) {ɛ}^{T} D ɛ & Equation 4 \\ ɛ = {[ {ɛ}_{xy} {ɛ}_{yy} {ɛ}_{zz} {γ}_{xy} {γ}_{yz} {γ}_{zx} ]}^{T} & Equation 5\end{matrix}$$

where ε is the total strain vector, σ is the stress vector and D is the 3D orthotropic stress-strain matrix.

The updated strain-energy density, ρₑ, can be normalized at operation 304 so that 0<ρₑ<1. In some cases, ρₑ is greater than at least about 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.1, 0.2, 0.3, 0.4, 0.5, 0.6, 0.7, 0.8, 0.9, 1, 2, 3, 4, 5 or more. In other cases, ρₑ is at most about 5, 4, 3, 2, 1, 0.9, 0.8, 0.7, 0.6, 0.5, 0.4, 0.3, 0.2, 0.1, 0.09, 0.08, 0.07, 0.06, 0.05, 0.04, 0.03, 0.02, 0.01, 0.009, 0.008, 0.007, 0.006, 0.005, 0.004, 0.003, 0.002, 0.001, or less. Next, the updated and normalized strain-energy density, ρₑ, can be evaluated to see if any change occurs when compared to the initial ρₑ=1 (e.g., in the first iteration of the process flow 300) or to the previous ρₑ (e.g., in the second and/or any subsequent iterations of the process flow 300) at operation 305. If there is no change or the change is less than a predetermined threshold the initial topology may be optimized and the process flow 300 may end. If the change in ρₑ is greater than a predetermined threshold, e.g., 0.01 or 0.001, the system and methods may repeat operations 302, 303, 304, and 305 until the change is below a predetermined threshold and/or another stopping criterion is met. In some cases, the predetermined threshold is greater than at least about 0.001, 0.002, 0.003, 0.004, 0.005, 0.006, 0.007, 0.008, 0.009, 0.01, 0.02, 0.03, 0.04, 0.05, 0.06, 0.07, 0.08, 0.09, 0.1 or more. In other cases, the predetermined threshold is at most about 1, 0.9, 0.8, 0.7, 0.6, 0.5, 0.4, 0.3, 0.2, 0.1, 0.09, 0.08, 0.07, 0.06, 0.05, 0.04, 0.03, 0.02, 0.01, 0.009, 0.008, 0.007, 0.006, 0.005, 0.004, 0.003, 0.002, 0.001, or less. The optimized initial topology may include a variable strain-energy density or a black and white topology.

With continued reference to FIG. 1, after the initial FEA for structural strength analysis and topology optimization at operation 102, the process flow 100 may proceed with generating a strength-based toolpath 103 to refine the optimization. The toolpath may be generated and optimized taking into account the constraints associated with the 3D printing. The optimization of the toolpath may involve additive FEA analysis operation 104. In some cases, the toolpath optimization may include optimizing geometric parameters and fiber orientation. At operation 103, the tool path may be generated based on structural strength information of the object to be printed derived from the input model, FEA analysis and/or topology of the object based on initial topology optimization. The toolpath can be generated through additive FEA and further optimized at operation 104. At a first iteration, the tool path generated by operation 103 may be an initial tool path. At operation 104, the initial tool path may be optimized by varying one or more toolpath parameters such as a raster angle of a layer, an infill density, a layer orientation, a perimeter thickness, a thickness of layer, or other geometric parameters, and/or fiber orientation to yield the tool path for the 3D-printer for printing the 3D object. The tool path may be optimized based on the additive FEA analysis result performed in operation 104. For instance, one or more parameters of the tool path may be adjusted to add/remove material in the areas that is determined to require more/less reinforcements according to the additive FEA analysis. The tool path optimization may also optimize the orientation of the material being deposited to minimize deformation and stresses in the part based on the loading requirements. In some cases, one or more parameters of the tool path may be adjusted based at least in part on adjusting strain-energy density across a plurality of regions of the 3D object or the model of the 3D object. For example, operation 104 can include adjusting the strain-energy density across a plurality of regions of the 3D object until a stopping criterion may be met, thereby yielding substantial uniformity in the strain-energy density across the plurality of regions. Operation 104 may further include optimizing fiber orientation based at least in part on the structural strength of the 3D object or the model of the 3D object, the topology of the 3D object or model of the 3D object, and/or geometric parameter(s).

The toolpath generated and optimized by the provided method may be a 3D toolpath. For example, the tools paths may have constant/variable spacing or width in a 3D curved surface. The toolpath generation and optimization may use a spline-based (e.g., is non-uniform rational B-spline) representation of the 3D model and the toolpath.

The toolpath may be generated using a toolpath generator module. Machine code (e.g., G/M code) may be generated by the generator module, which can be used to drive a 3D printer to print the object starting from a 3D input model. The generated machine code can instruct the printer in various movements (e.g., layer by layer, causing material deposition), thereby resulting in a 3D virtual part. Such a toolpath generation process can be characterized by several parameters (e.g., deposition bead width and height, infill density and pattern, print speed) that enable the user to fine tune the printing process.

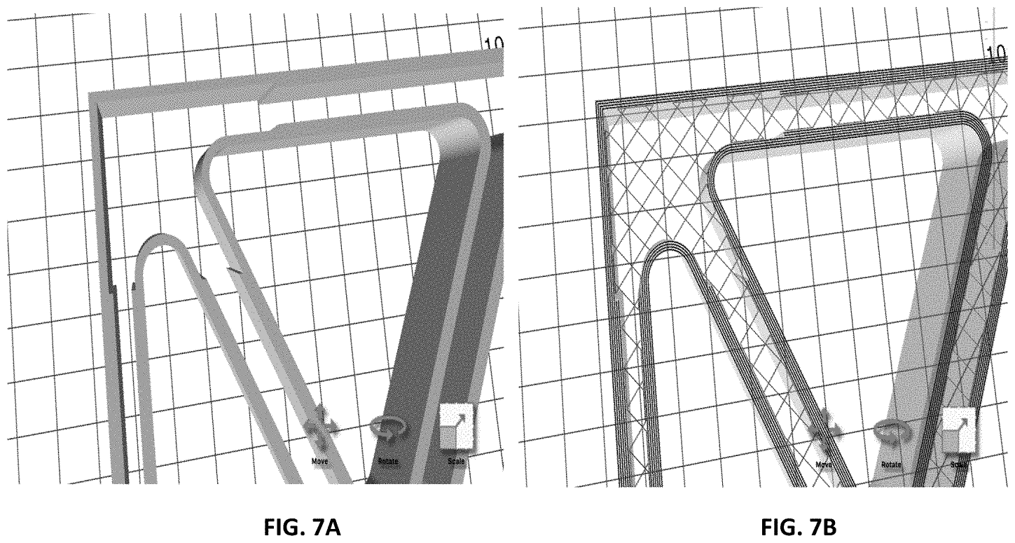

In some cases, the ability to drive the toolpath generation parameters may be driven based on additive finite element analysis (AFEA) results. For example, the toolpath generator can add or remove material in specific areas that the AFEA has identified as needing more or less reinforcement (e.g., as shown in FIGS. 7A-7B). Referring to FIGS. 7A-7B, a 3D model of the object to be printed is shown. The 3D model may include walls reinforced as a result of FEA analysis (FIG. 7A) and resulting toolpath (FIG. 7B). It can also optimize the orientation of the material being deposited to minimize deformation and stresses in the object based on the loading requirements. This allows the user to fully take advantage of printing with anisotropic material. In some cases, the toolpath generator module may receive the structural analysis result (e.g., stress vectors from FEA analysis) produced by the previous operation (e.g., topology optimization) and generate toolpaths based on the expected loads. The toolpath may be continuously optimized based on the additive finite element analysis (AFEA) results as described above. In some cases, if the process may return to the topology optimization operation if the performance of the 3D object does not meet pre-determined performance criterion.

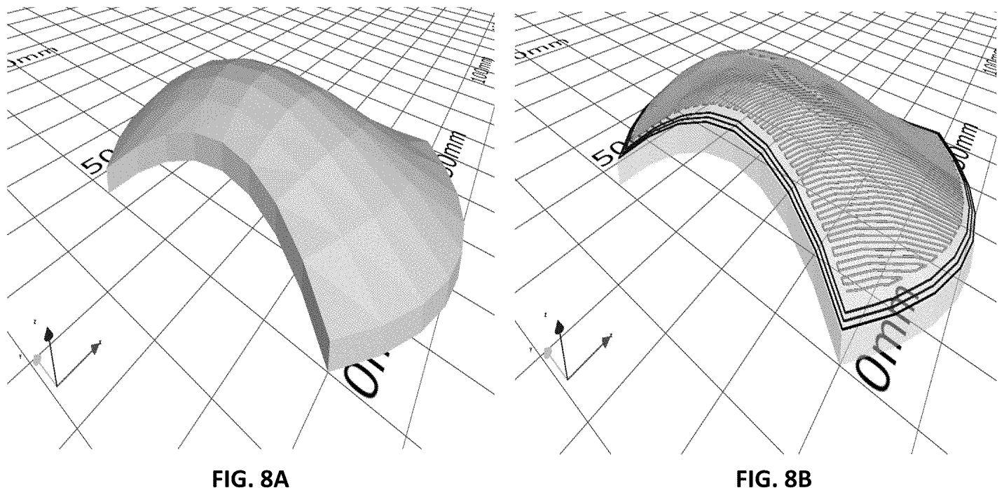

The toolpath generator herein advantageously can enable creating fully 3D toolpaths. Most traditional 3D printers operate by depositing a layer of material in the XY plane, moving the tool head up in the Z direction, and depositing the next layer, again, in the XY plane at the new elevation. This method generally fails to provide much consolidation and strength in the Z direction of a part because the object may be essentially just a stack of layers in the Z direction. A full-3D path can be one where the print head moves and deposits material in all the X, Y, and Z directions simultaneously, in a single deposition path, e.g., FIGS. 8A-8B. This can be advantageous when printing parts with freeform surfaces (e.g. airplane wings, domes, propellers) and parts that require non-planar internal structures to achieve desired mechanical properties. A commercial CAD modeling kernel (e.g., ACIS modeler) can be used herein for processing and manipulating CAD geometry and perform computations at the level of precision attainable by the AM process/printer. After generation a toolpath can be instantly simulated in a virtual printer to verify correctness of each layer/path as well as the entire object that can be supposed to be printed.

After the initial FEA for structural strength analysis and topology optimization at operation 102, the process flow 100 may refine the optimization consistent with the tool path and any constraints associated with the 3D printing. Toolpath optimization such as optimization of geometric parameters and fiber orientation may be performed after such initial FEA and topology optimization. The geometric parameters may provide details regarding the construction of the object to be printed, alone or in combination with the fiber orientation, they may drive the tool path strategy.

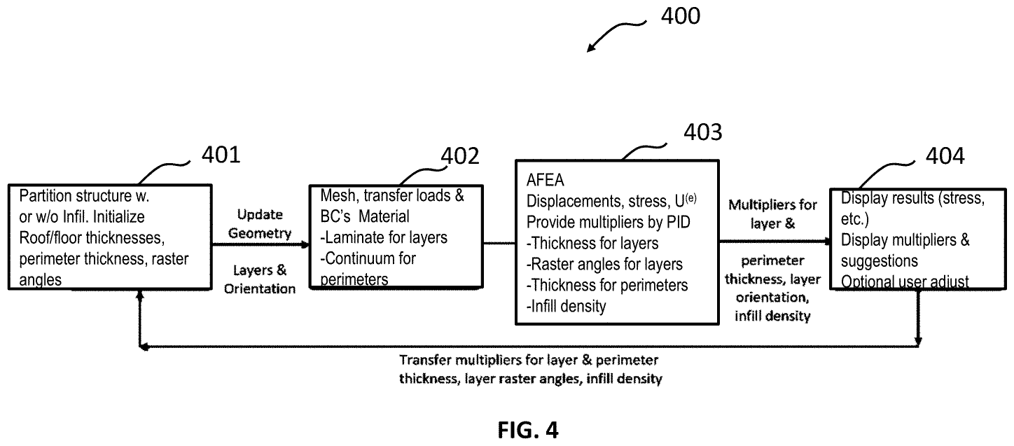

FIG. 4 shows an example process of generating and optimizing a toolpath 400. The process 400 may be a sub-process flow for operations 103 and 104 described in FIG. 1. The toolpath may be optimized based on the AFEA analysis result and printing constraints. Referring to FIG. 4, the 3D object of interest may be partitioned into regions with or without infill 401. Such regions may include different perimeter thicknesses, layer thicknesses and raster angles (for roof and floors) and infill densities. Parameters (e.g., roof and/or floor thickness, perimeter thickness, raster angle) may be initialized at operation 401, in some cases, with user-specified values or values generated automatically by a computer program. At operation 402, a finite element mesh may be initialized with loads and boundary conditions, material information may be specified, layers of the object may be specified as laminate structures, and perimeters may be specified as continuum. In operation 403, AFEA may be performed so that strain-energy density may be calculated, and parameters (e.g., perimeter thicknesses, layer thicknesses and raster angles (for roof and floors), and infill densities) can be updated based on the AFEA. The updated parameters and/or other information (e.g., stress) may be displayed to a user at operation 404. The user may adjust the value(s) of the displayed information, and the subsequent sub-process may repeat operations 401-404 for one or multiple iterations until a stopping criterion has been met. PID is property identification, or, property ID and can act as tags that are used to identify different regions of the structure. The mulitpliers herein can be normally thickness multipliers, (e.g., the local thickness of a floor, roof or wall).

In optimization operations in FIG. 4, the topology of the 3D object may be fixed whereas toolpath parameters such as the geometry parameters (e.g., raster angles or infill densities) or fiber orientations may be adjusted to achieve the optimization objective. For example, the geometry parameters may be adjusted to achieve a uniform strain-energy density in the partitioned regions and/or subcomponents of those regions. For example, the floor thickness may be optimized by averaging the strain-energy density of all the elements in a particular section of the floor, increasing thicknesses for regions that have higher than average strain energy density, U_{avg}, and/or decreasing thicknesses for regions that have lower than average U_{avg} values. This may be repeated for either a selected number of iterations or until the averaged strain energy densities stop changing within a user defined tolerance or threshold.

The systems and methods disclosed herein may be applied to objects that can be characterized by parameters such as perimeter thicknesses, layer thicknesses, raster angles (for roofs and floors), and infill densities. However, the systems and methods can also be applied to 3D slicing algorithms and other parameters can be selected as variables for optimization. In some cases, the designer may create a design without such constraint (e.g., a sphere does not have a roof, wall, and/or floor structure). For example, the 3D slicing algorithm may be applied to generate a 3D tool path on a curved surface, and/or 3D volume/region.

With reference to FIG. 1, one or more operations may be iterated (e.g., operations 103-104 or operations 102-104) until a stopping criterion is met. When operations 102-104 are repeated, the optimized tool path, fiber orientation, and/or other information, such as geometric parameters are fed into operation 102 for updated FEA and topology optimization. The updated FEA and topology optimization can then be used again for strength-driven toolpath generation 103, and further toolpath optimization and/or fiber orientation optimization at operation 104 until a stopping criterion has been met. The stopping criterion may be a threshold (e.g., a quality threshold). The stopping criterion may include uniformity in strain-energy density of the 3D object or model of the 3D object. The stopping criterion may be user-defined or automatically adjusted by a computer program.

After meeting a stopping criterion, the optimized toolpath from operation 104 can be simulated in the virtual printer module so the final appearance of the 3D object may be visualized and potential issues with the toolpath and the model as it is being manufactured in operation 105 may be determined. Operation 105 may include simulating printing of the 3D object using the 3D printer tool path to yield a simulated 3D object. Analysis of the simulated 3D object may be performed by interacting with the virtual printed 3D object by a user to determine whether the simulated 3D object has any issues or defects. If the simulated 3D object meets the predetermined threshold, printing instructions can be generated comprising the optimized tool path for use by a 3D printer.

In some cases, the virtual simulator or virtual printer may be configured to interactively visualize the toolpaths (e.g., FIGS. 8A-8B) and detect potential issues such as overlapping and overhanging paths, collisions of the printing tool with the unfinished part (e.g., in complex or full-3D toolpaths) and structural strength of the unfinished part to ensure that the object does not collapse as the print progresses. These may allow for defects or design flaws being detected by the virtual simulator rather than during a real 3D print job on a real 3D printer, thus advantageously saving time and resources.

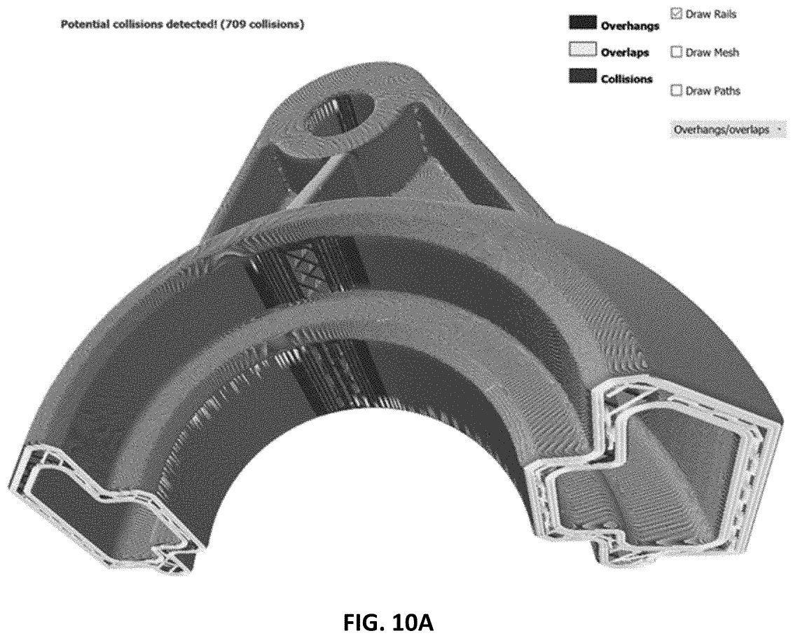

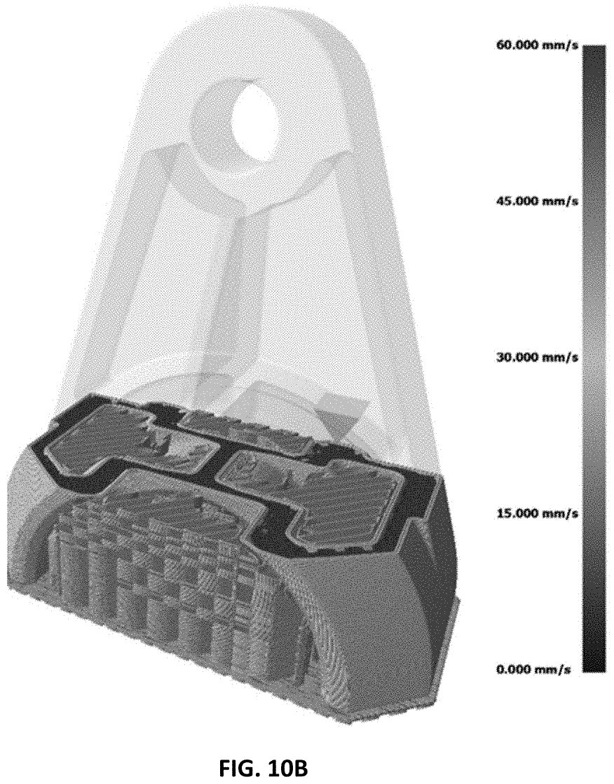

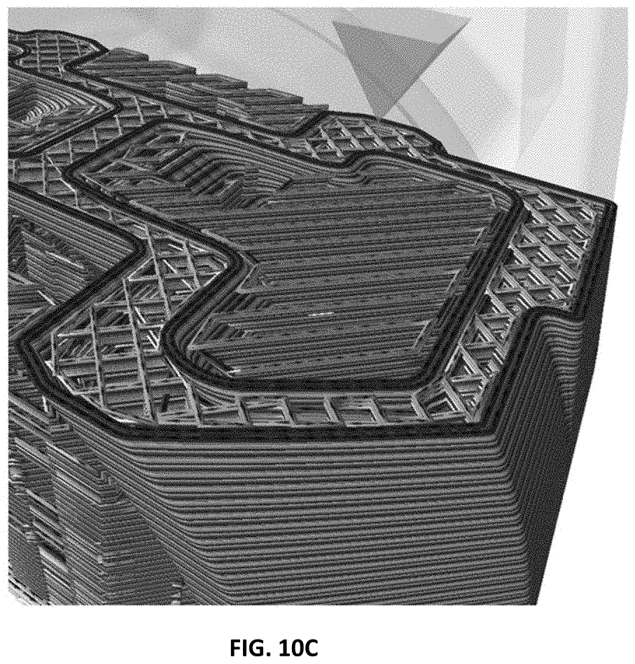

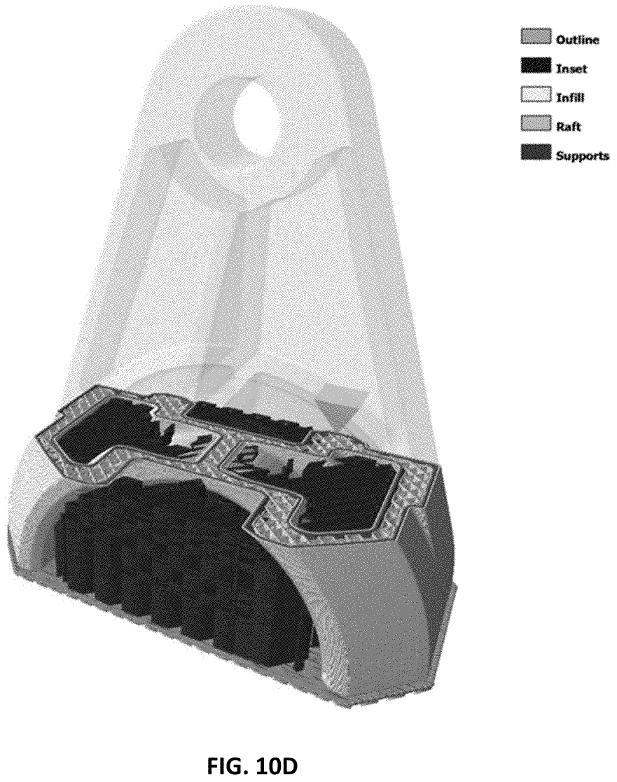

The virtual simulator or printer herein can read machine code created by the toolpath generator and simulates it either in real-time or with the desired speedup factor. 3D printing methods (e.g., extrusion or non-extrusion processes) can be visualized. The toolpath can be divided into discrete simulation elements whose size may depend on the desired precision and speed of the simulation (e.g., higher precision correlates with slower simulation). The geometry of each element can be calculated from the current extrusion rate, movement speed, and/or deposition width and height. After the filament geometry is estimated, potential geometric problems can be detected such as overhangs that occur when the filament has no support from underlying filaments or is positioned far from an already deposited filament. Without support, the filament may collapse under gravity, leading to distortions in the printed object. Since the filament can stretch over some distance without significant distortions, an overhang distance tolerance may be set. Overlaps can occur when filaments are located close to one another. Overlaps can result in collisions of the print head with the deposited part due because of material buildups at overlaps. Collisions may result from errors in the toolpath allowing the print head to hit the unfinished part or material buildup from overlaps. The printing head colliding with the object can effectively stop the entire print process. FIGS. 10A-10D show various visualization modes of the virtual simulator or virtual printer-overhangs, overlaps and collisions (FIG. 10A), tool speed (FIG. 10B), layers with filament directions (FIG. 10C), machine code categories (FIG. 10D).

The simulated 3D object and/or simulation of 3D printing of a 3D object can be presented to a user using the virtual simulator herein can be presented to a user using the virtual simulator herein. Such presentation can be on a user interface, e.g., GUI. The user may interact with the simulated 3D project via the user interface to view and/examination simulation of the 3D object. Such presentation of simulated 3D object for simulated 3D printing of the 3D object can advantageously enable the user to conveniently visualize geometric problems and other entities or properties of the 3D object.

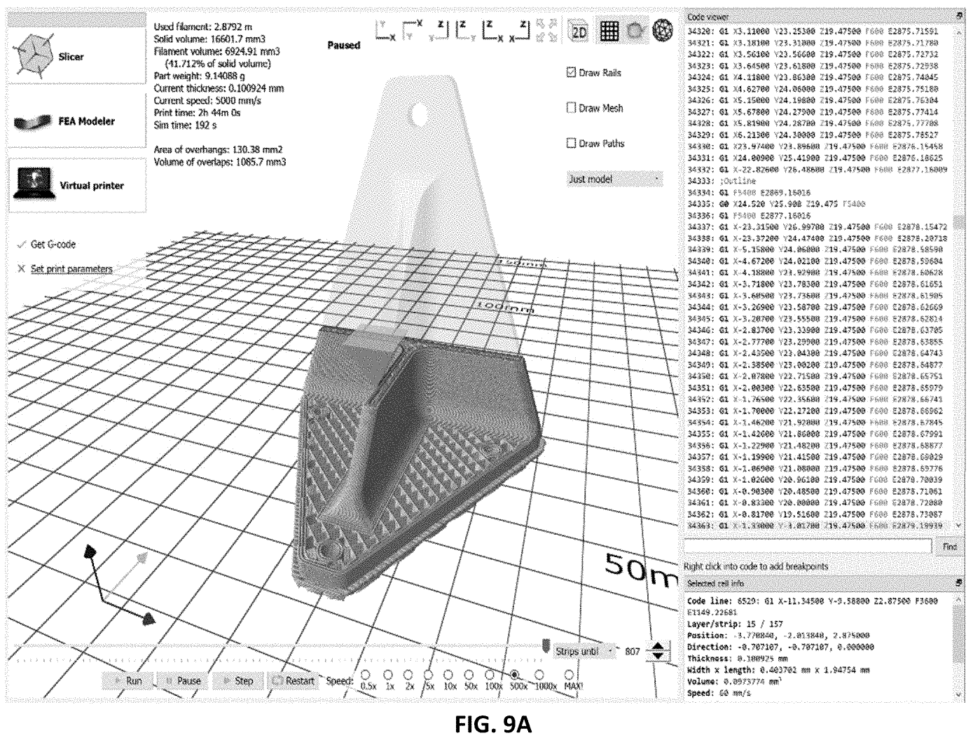

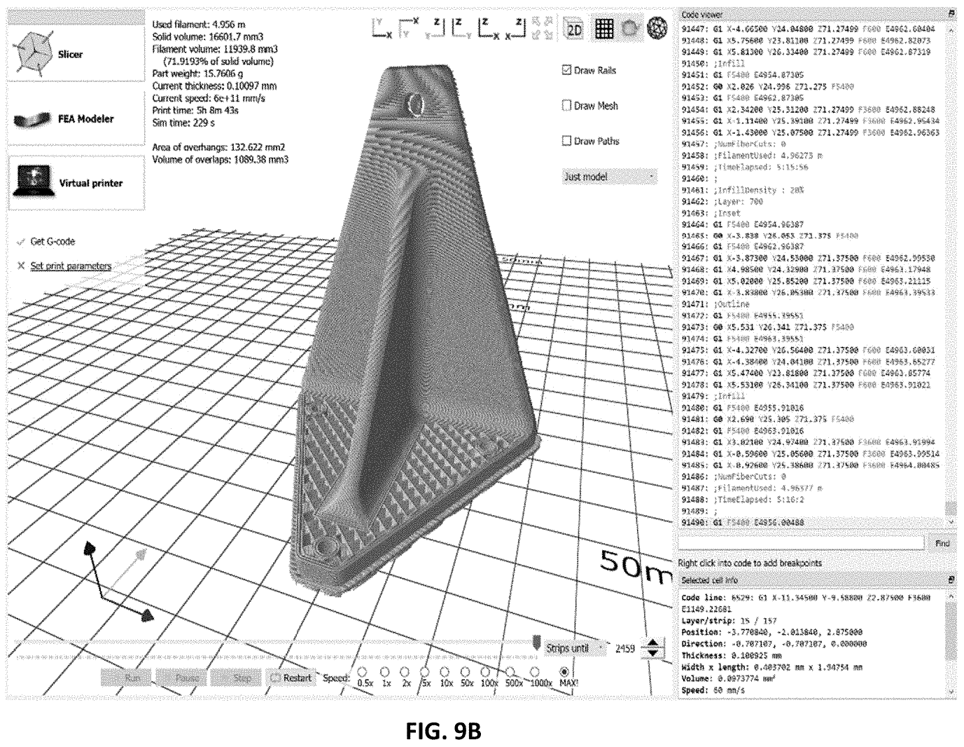

Apart from geometric problems, additional parameters may be visualized on the simulated object (e.g., FIGS. 9A-9B), such as distances between filaments, extrusion rate, layer thickness, movement speed, and machine code categories (e.g., outline, infill, support). It can also be possible to visualize additional data obtained by metrology. For example, a point cloud obtained from scanning the real object may be visualized to determine how the points correspond to the surface of the simulated object. Various statistics can be displayed as well. The statistics may comprise one or more elements selected from filament usage, part volume, weight, estimated print time, and total area or volume of overhangs and overlaps.

To evaluate the structural strength of the object during the printing, the virtual printer or simulator can extract the boundary 3D mesh on-the-fly and send it to the FEA module for evaluation. This may help expose structural issues during the printing of the unfinished part as well as thermal warping. Moreover, the extracted 3D mesh can be compared to the original geometry file to check for any deviations from the expected geometric shape.

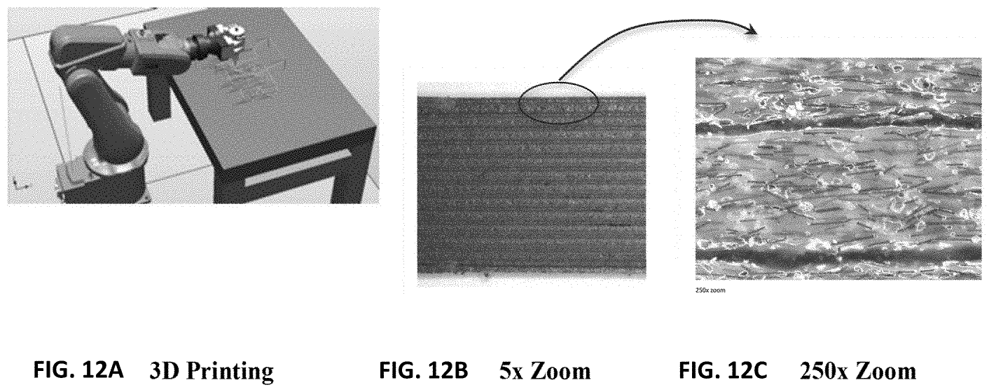

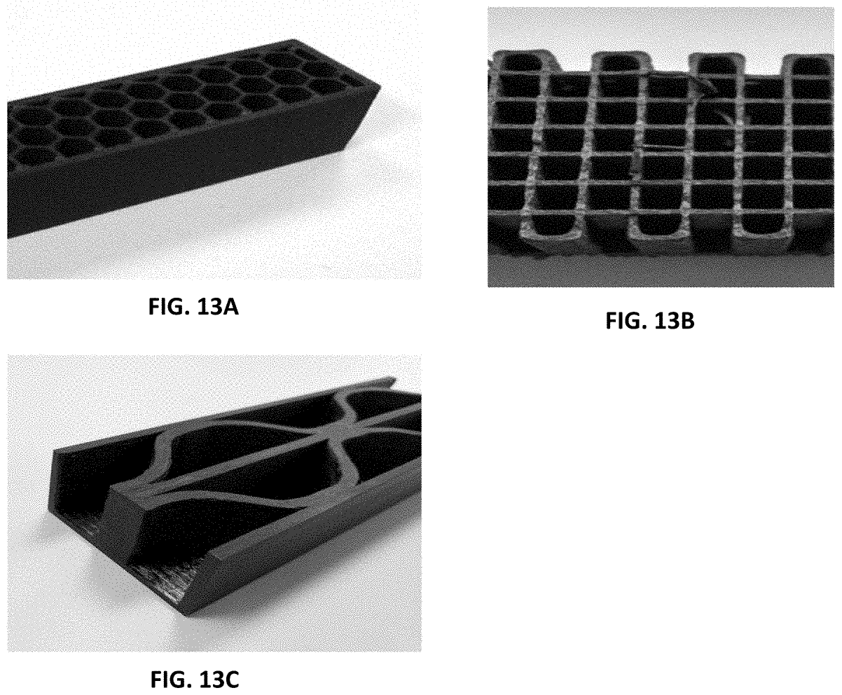

Advantageously, 3D printing of discontinuous and/or continuous fiber reinforced material can be used to tailor the mechanical properties of the 3D object. FIGS. 12A-12C show with discontinuous fiber material printed using an FDM process, one can align the fibers in a preferred orientation (e.g., horizontal in FIGS. 12A-12C). When printing continuous fibers, the fiber orientation can be aligned as desired. This alignment may produce anisotropic material properties and both the stiffness and strength of the material may depend upon the print direction. For high performance composite parts such a feature can be advantageous. When the internal stresses are large, the parts in the direction of printing may be stiffened or strengthened. In regions where the stresses are low, the amount of material may be reduced using a sparse infill. Examples of different sparse infill patterns available are shown in FIGS. 13A-13C. Table 1 presents representative sample mechanical properties in the fiber and transverse directions for discontinuous and continuous fiber material. The differences between property measurements for the continuous fiber material are greater than that of the discontinuous fiber material.

TABLE 1

| | Discontinuous | Continuous |
|---|---|---|
| Property | (FDM) | (DEM) |
| Young's Modulus - E₁ (GPa) | 19 | 76 |
| Young's Modulus - E₂ (GPa) | 4.0 | 5.1 |
| Tensile strength tension - Sₐ^{T} (MPa) | 120 | 840 |
| Tensile strength tension - S_{b}^{T} (MPa) | 80 | 18 |

where a = Fiber or Print Direction, b = Transverse to Fiber or Print Direction.

Because of the flexibility in tailoring mechanical properties, the design of optimal printed 3D parts may be complex. For example, the fiber orientation, the presence of sparse infill material and manufacturability may need to be determined. The systems and methods disclosed herein (e.g., process flow 100) may be used to both simplify the analysis and design approach while at the same time providing accurate simulation.

In another aspect, the present disclosure provides for a computer-implemented system for printing a 3D object. The system may comprise a computer memory, GUI, and one or more computer processors operatively coupled to the computer memory. The one or more computer processors may be individually or collectively programmed for processing a computer model of the 3D object to generate a strength or stress profile of the computer model. The computer processors may be programmed for using at least (i) the strength or the stress profile from (a) and (ii) a topology of the 3D object to generate a 3D printer tool path for printing the 3D object. Next, the computer processors may be programmed for simulating printing of the 3D object using the 3D printer tool path to yield a simulated 3D object, analyzing the simulated 3D object to determine whether the simulated 3D object meets a threshold, and if the simulated 3D object meets the threshold, generating printing instructions comprising the tool path for use by a 3D printer to print the 3D object.

### Software and GUI

Although there has been some development of AM-focused software tools, different software packages may be required to enable the entire AM process, hindering productivity and creativity. The present disclosure provides software tools that may seamlessly integrate design, optimization, simulation or fabrication processes. The present disclosure provides an improved optimization method allowing for simultaneous system and structural design and tool path generation.

The present disclosure herein includes a web application, mobile application, or software tool to aid all aspects of the AM processes such as computer aided design, engineering, and manufacturing. Such application or software tools can include multiple software modules. The software modules may be configured for visualization and processing of end-user's CAD models, automated design optimization, AFEA, and print and process simulation, which together may assist the toolpath generation. The software modules and functionalities may be fully integrated into a single graphical user interface (GUI) which is portable to multiple hardware platforms. Such applications may be used in the areas of optimization, FEA, and toolpath planning.

AM can be viewed as materialization of a digital design Error! Reference source not found because AM processes take a digital representation (e.g., a model) of an object and process the digital representation to generate information for guiding the process or machine to generate a physical object. The traditional paradigm attempts to leverage existing software solutions, which were originally developed for subtractive manufacturing, and tie them together for AM, resulting in differing levels of complexity and ease of use.

For example, although CAD developers have integrated FEA into their solutions, the focus maybe on subtractive processes and simplified analyses intended for designers that are often inadequate for the AM paradigm. Another complicating factor in optimizing the structural design is the absence of material models in ways that can be used along with the other elements of the process, such as the toolpath generation. Current finite element packages comprise optimization which is accessed using a “block structure” type of connectivity. However, tight coupling to the slicing software (in AM) can be absent. Although some optimization tools have been reported to include topology optimization and AM specific constraints, the incorporation of process parameters that involve additional physics such as thermal and nonlinear material response may not be scheduled using the FEA solutions built into CAD systems. A process simulation module (e.g., a virtual printer) that includes process or toolpath specific metrics (e.g., overhang detection, void or gap detection) in the design process can be essential but rarely available for AM processes.

Robust, process-aware optimization design tools may be necessary to account for uncertainties in materials, processes, and requirements in AM. To address this gap, the present disclosure includes a fully integrated computer aided design (CAD), computer aided engineering (CAE), and/or computer aided manufacturing (CAM) software tool that is focused on multiple aspects of the AM process with an emphasis on the FFF process. Such software tools can contain seamlessly integrated modules for design optimization, FEA, toolpath generation and virtual 3D print simulation (e.g., as shown in FIG. 1). The software tool disclosed herein may hide most of the module interaction from the user, allow for individual analytic capabilities suited for composites and 3D printing and not require the user to purchase multiple (often expensive) software packages. These general-purpose modules can run in a single user interface (UI) which is intuitive and easy to use by non-experts in areas of optimization, FEA and toolpath planning.

The systems and methods herein can include a software system. In order to generate the parametric surfaces and solids, a GUI can be developed. In some cases, the GUI can read in CAD files, for example, STL, STEP or IGES. From these files, the 3D geometry can be partitioned into 3D regions, each region defining a solid (e.g., a shell can be defined as a solid with a thin thickness) object. CAD files with parametrical definitions (e.g., STEP files) may be preferred. But conceptually, files, such as STL files, can be converted to parametric representations.

The parametric or other primitive based geometry file can be partitioned manually using a GUI. For applications disclosed herein, the geometry may be partitioned in such a manner that the surface edges and/or solid surfaces are aligned in preferred directions. This can facilitate the assignment of fiber orientation along particular directions. In some cases, the tool path described herein may not follow the geometric edges of the surfaces or solids. In other cases, a specification of how the fibers can be preferentially oriented inside any layer may be included. The algorithms can be used to generate a tool path of constant width w and subsequent layers of constant thickness h. The desired tool path can be guided by automatic (e.g., finite element stress) analyses or manual analysis. All of these options may be supported by the GUI, including, automatic import of preferred fiber directions from finite element simulations.

Software technologies may be leveraged in order to differentiate its product and help deliver high performance parts. Certain users may not wish to purchase their own specialized computing resources. Appropriate software may be ported and executable in-the-cloud. This can ensure that a developed code may not be operating system specific. The system may be a Windows, Linux, or Mac operating system. In-the-cloud software can include improvement of throughput of computer intensive jobs. The computer intensive jobs can comprise FEA or preparation of CAD models through slicing algorithms. Additionally, in-the-cloud computing can allow for the ability to utilize multi-processing and parallelization techniques. The developed software may be enabled to leverage these programming paradigms.

### Computer Systems

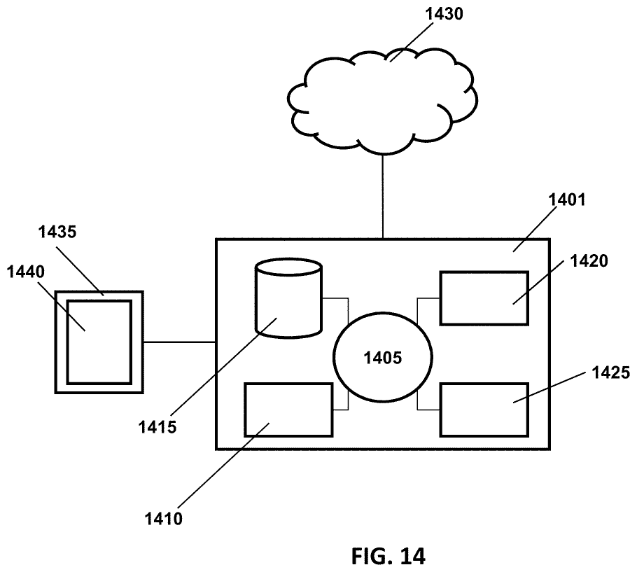

The present disclosure provides computer systems that may be programmed or otherwise configured to implement devices, methods and systems of the present disclosure. FIG. 14 shows a computer system 1401 that is programmed or otherwise configured to implement 3D printing methods and systems of the present disclosure. The computer system 1401 can regulate various aspects of methods the present disclosure, such as, for example, processing a computer model of the 3D object to generate a strength or stress profile of the computer model.

The computer system 1401 includes a central processing unit (CPU, also “processor” and “computer processor” herein) 1405, which can be a single core or multi core processor, or a plurality of processors for parallel processing. The computer system 1401 also includes memory or memory location 1410 (e.g., random-access memory, read-only memory, flash memory), electronic storage unit 1415 (e.g., hard disk), communication interface 1420 (e.g., network adapter) for communicating with one or more other systems, and peripheral devices 1425, such as cache, other memory, data storage and/or electronic display adapters. The memory 1410, storage unit 1415, interface 1420 and peripheral devices 1425 are in communication with the CPU 1405 through a communication bus (solid lines), such as a motherboard. The storage unit 1415 can be a data storage unit (or data repository) for storing data. The computer system 1401 can be operatively coupled to a computer network (“network”) 1430 with the aid of the communication interface 1420. The network 1430 can be the Internet, an internet and/or extranet, or an intranet and/or extranet that is in communication with the Internet. The network 1430 in some cases is a telecommunication and/or data network. The network 1430 can include one or more computer servers, which can enable distributed computing, such as cloud computing. The network 1430, in some cases with the aid of the computer system 1401, can implement a peer-to-peer network, which may enable devices coupled to the computer system 1401 to behave as a client or a server.

The CPU 1405 can execute a sequence of machine-readable instructions, which can be embodied in a program or software. The instructions may be stored in a memory location, such as the memory 1410. The instructions can be directed to the CPU 1405, which can subsequently program or otherwise configure the CPU 1405 to implement methods of the present disclosure. Examples of operations performed by the CPU 1405 can include fetch, decode, execute, and writeback.

The CPU 1405 can be part of a circuit, such as an integrated circuit. One or more other components of the system 1401 can be included in the circuit. In some cases, the circuit is an application specific integrated circuit (ASIC).

The storage unit 1415 can store files, such as drivers, libraries and saved programs. The storage unit 1415 can store user data, e.g., user preferences and user programs. The computer system 1401 in some cases can include one or more additional data storage units that are external to the computer system 1401, such as located on a remote server that is in communication with the computer system 1401 through an intranet or the Internet.

The computer system 1401 can communicate with one or more remote computer systems through the network 1430. For instance, the computer system 1401 can communicate with a remote computer system of a user (e.g., customer or operator of a 3D printing system). Examples of remote computer systems include personal computers (e.g., portable PC), slate or tablet PC's (e.g., Apple® iPad, Samsung® Galaxy Tab), telephones, Smart phones (e.g., Apple® iPhone, Android-enabled device, Blackberry®), or personal digital assistants. The user can access the computer system 1401 via the network 1430.

Methods as described herein can be implemented by way of machine (e.g., computer processor) executable code stored on an electronic storage location of the computer system 1401, such as, for example, on the memory 1410 or electronic storage unit 1415. The machine executable or machine readable code can be provided in the form of software. During use, the code can be executed by the processor 1405. In some cases, the code can be retrieved from the storage unit 1415 and stored on the memory 1410 for ready access by the processor 1405. In some situations, the electronic storage unit 1415 can be precluded, and machine-executable instructions are stored on memory 1410.

The code can be pre-compiled and configured for use with a machine having a processer adapted to execute the code, or can be compiled during runtime. The code can be supplied in a programming language that can be selected to enable the code to execute in a pre-compiled or as-compiled fashion.

Aspects of the systems and methods provided herein, such as the computer system 1401, can be embodied in programming. Various aspects of the technology may be thought of as “products” or “articles of manufacture” typically in the form of machine (or processor) executable code and/or associated data that is carried on or embodied in a type of machine readable medium. Machine-executable code can be stored on an electronic storage unit, such as memory (e.g., read-only memory, random-access memory, flash memory) or a hard disk. “Storage” type media can include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software. As used herein, unless restricted to non-transitory, tangible “storage” media, terms such as computer or machine “readable medium” refer to any medium that participates in providing instructions to a processor for execution.

Hence, a machine readable medium, such as computer-executable code, may take many forms, including but not limited to, a tangible storage medium, a carrier wave medium or physical transmission medium. Non-volatile storage media include, for example, optical or magnetic disks, such as any of the storage devices in any computer(s) or the like, such as may be used to implement the databases, shown in the drawings. Volatile storage media include dynamic memory, such as main memory of such a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer readable media may be involved in carrying one or more sequences of one or more instructions to a processor for execution.

The computer system 1401 can include or be in communication with an electronic display 1435 that comprises a user interface (UI) 1440 for providing, for example, a print head tool path to a user. Examples of UI' s include, without limitation, a graphical user interface (GUI) and web-based user interface.

Methods and systems of the present disclosure can be implemented by way of one or more algorithms. An algorithm can be implemented by way of software upon execution by the central processing unit 1405. The algorithm can, for example, partition a computer model of a part and generate a mesh array from the computer model.

The computer system 1401 can include a 3D printing system. The 3D printing system may include one or more 3D printers. A 3D printer may be, for example, a fused filament fabrication (FFF) printer. Alternatively or in addition to, the computer system 1401 may be in remote communication with the 3D printing system, such as through the network 1430.

### EXAMPLE 1

### Box Beam Structural Analysis and Optimization

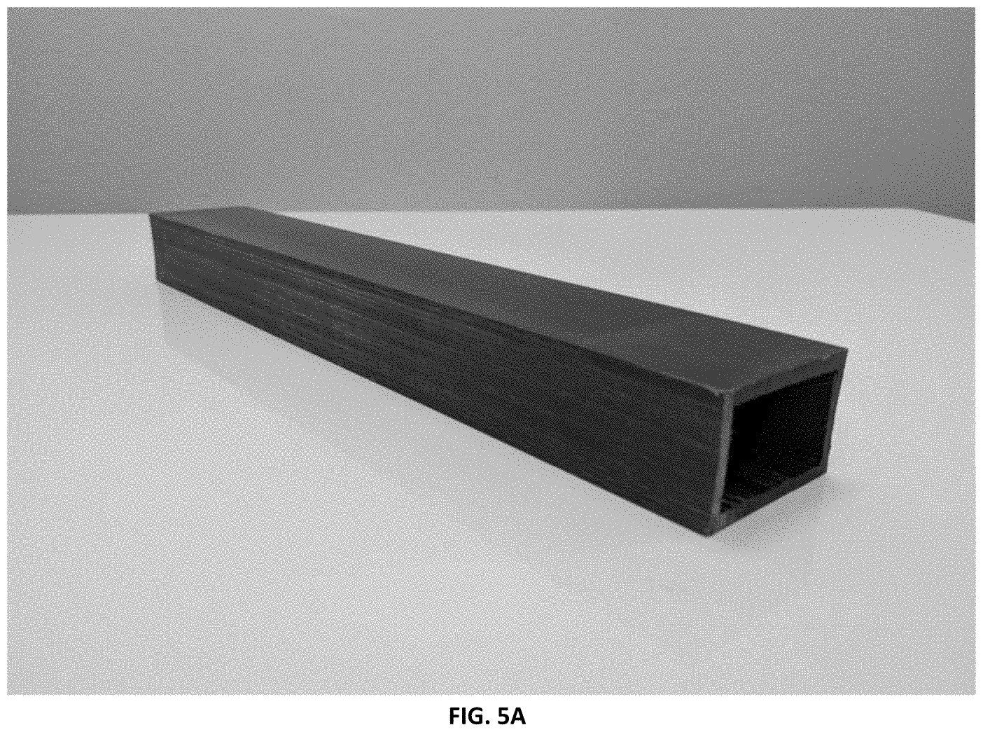

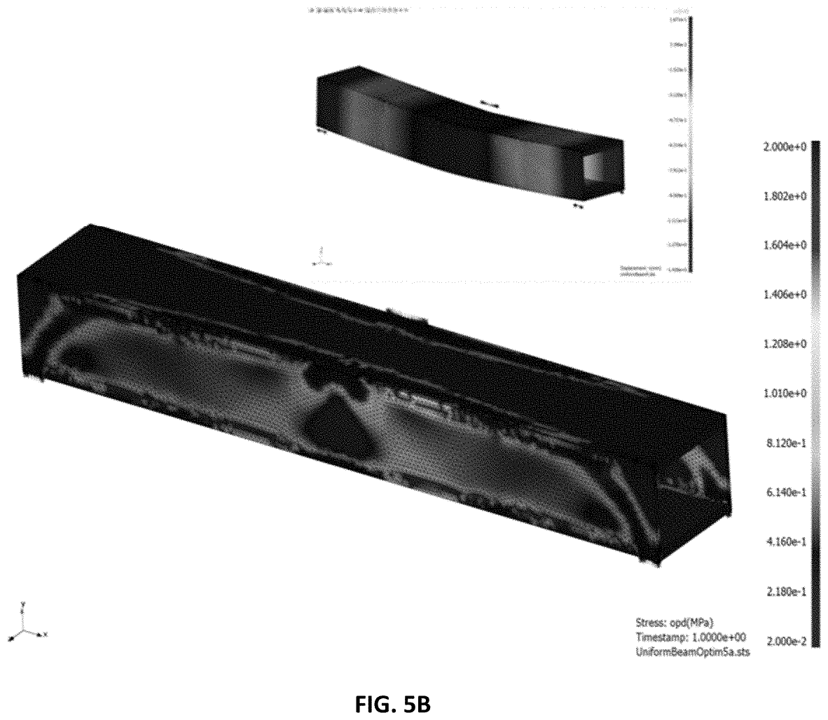

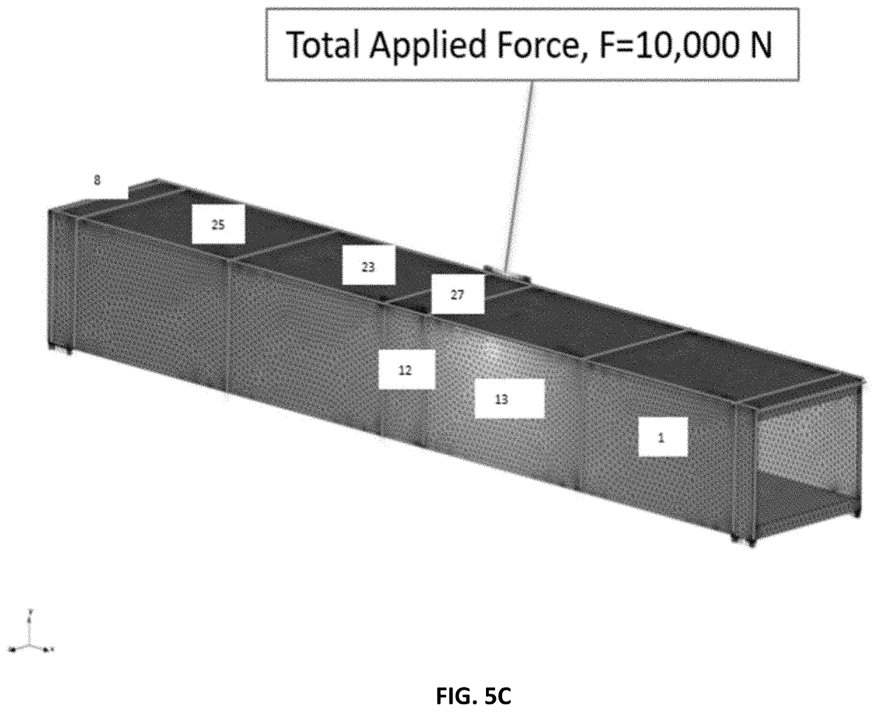

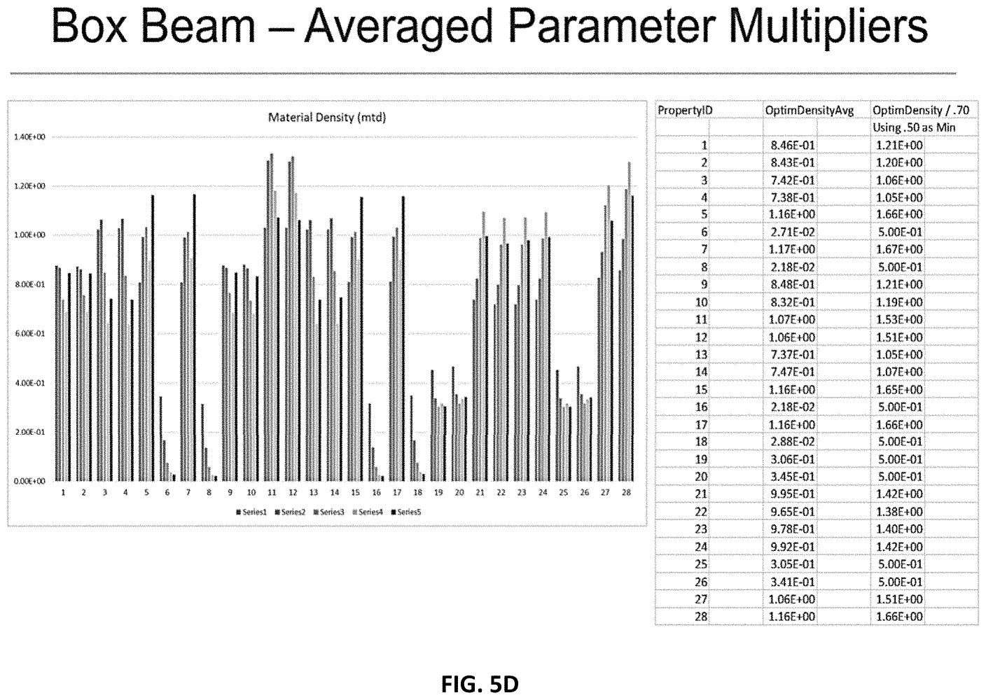

Box beams are used as structural elements in many different systems. FIG. 5A shows a box beam printed using continuous carbon fiber in a directed energy deposition system. FIG. 5B shows the initial FEA and topology optimization of a box beam. The upper portion of FIG. 5B shows deformed shape and contours of the vertical deflection. The lower portion of FIG. 5B show contours of optimization strain-energy density parameter, ρₑ, (red indicates higher density, while purple indicates lower). Lower values of ρₑ indicate positions where material could be removed from the system. Here the user decided against removing material which results in a truss-like structure as opposed to the desired box-beam form. Instead, the user used the geometry optimization by AFEA at operation 104. The box beam was segmented as indicated in FIG. 5C. In this case a total of 28 segments are defined. The segment definitions can be constructed using the built-in graphical interface or can be automatically driven by the initial topology optimization. Using operation 104, we perform the structural analysis and average strain energy densities over the segments. FIG. 5D shows a sequence of geometry parameter multipliers, which are used to modify perimeter (wall), floor, and ceiling thicknesses. A similar approach is used to define infill density and preferred raster angles. In FIG. 5D, the multipliers for the 28 regions are indicated and five iterations of the optimization are performed. The resulting weight reduction is 30% and subsequent re-analysis shows little change in deflections and peak stresses compared to the baseline.

### EXAMPLE 2

### Truss Structure Analysis and Optimization

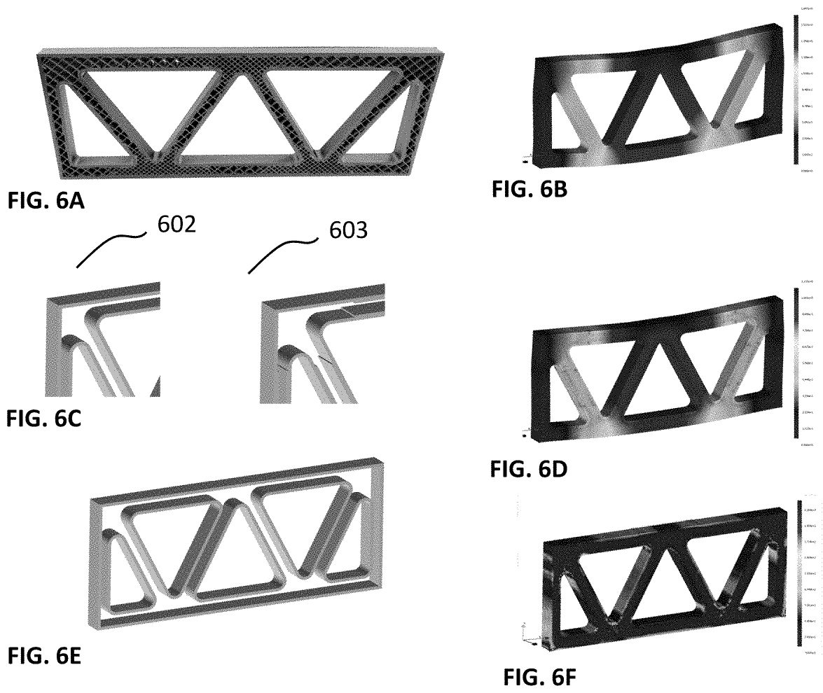

Truss structures are commonly used structural elements. Truss-like structures can be shown to be optimal in certain situations and are often predicted through topology optimization studies. In this example, it is assumed that the basic topology of a truss-like structure has been defined and optimization needs may be refined by determining the distributions of perimeter thicknesses and infill density. Although roof and ceiling can be included, the user eliminates them in this example. This can help reduce build time and weight. FIGS. 6A-6F show the initial truss structure and the sequence of analyses and optimizations.

FIG. 6A is a 3D printed structure showing the infill and perimeter walls. For this example the user did not include the floor or ceiling, therefore, one can see the infill density pattern. FIG. 6B shows the initial finite element structural analysis which assumed a uniform perimeter thickness and infill density (the uniform perimeter wall thicknesses are illustrated in FIG. 6E. The infill is modeled as a homogenized material using homogenization theory therefore, the model appears solid. After applying the FEA geometry optimization operation, thicknesses of the perimeter walls are changed as illustrated in FIGS. 6C and 6E. The left 601 of FIG. 6C shows the uniform wall thicknesses while the right 602 of FIG. 6C shows the optimized geometry with variable perimeter wall thicknesses. The analysis is then repeated using additive FEA (AFEA) with the results shown in FIGS. 6D and 6F. FIG. 6D shows the total displacements which are reduced by about 30% compared to the initial model as in FIG. 6B. This reduction in displacement is due to both the perimeter wall thickness and material orientation optimizations. FIG. 6F shows the effective stress plots that show a peak effective stress of around 245 MPa which is well within the material allowable in this region. Other post-processing options can allow for direct factors-of-safety examination using different composite failure criteria and plot a variety of stress related metrics.

### EXAMPLE 3

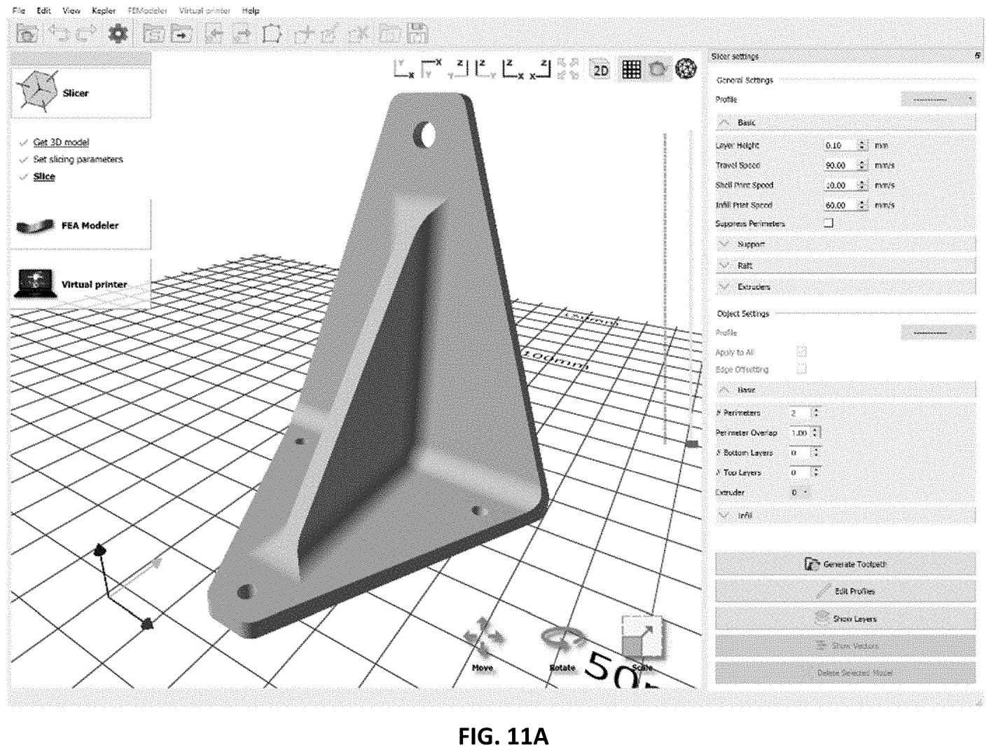

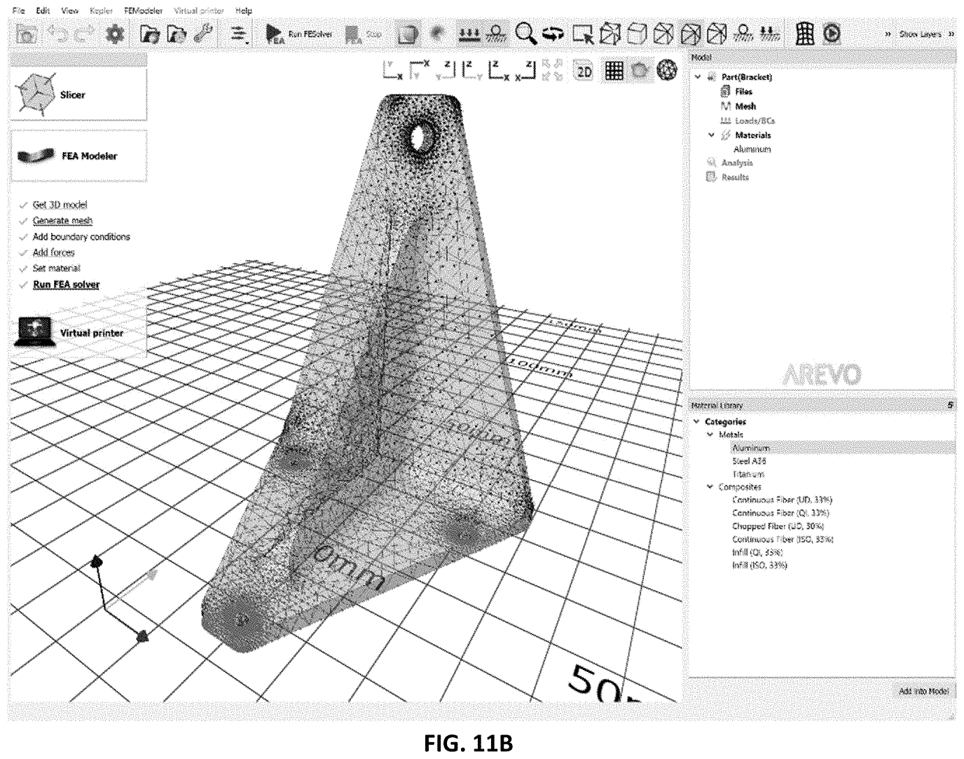

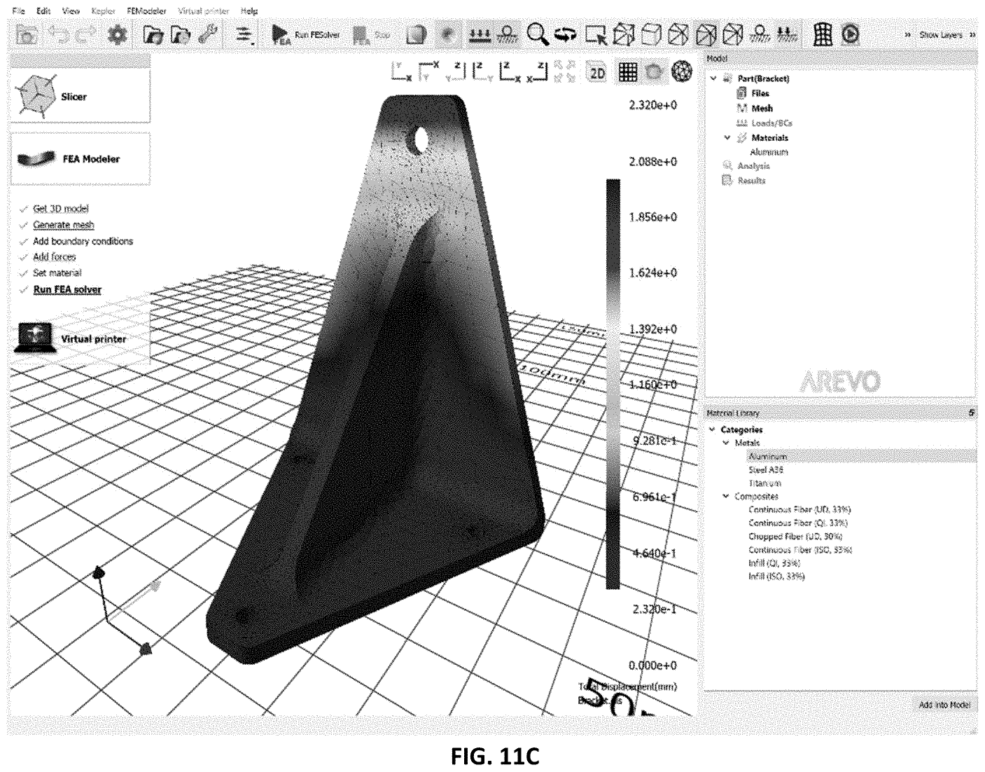

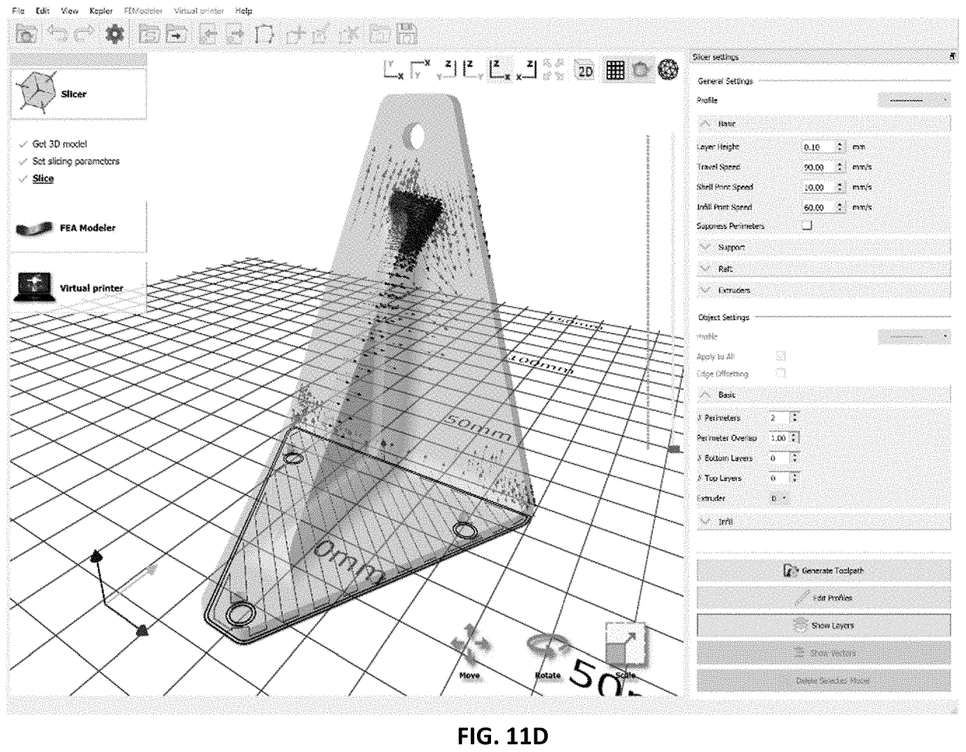

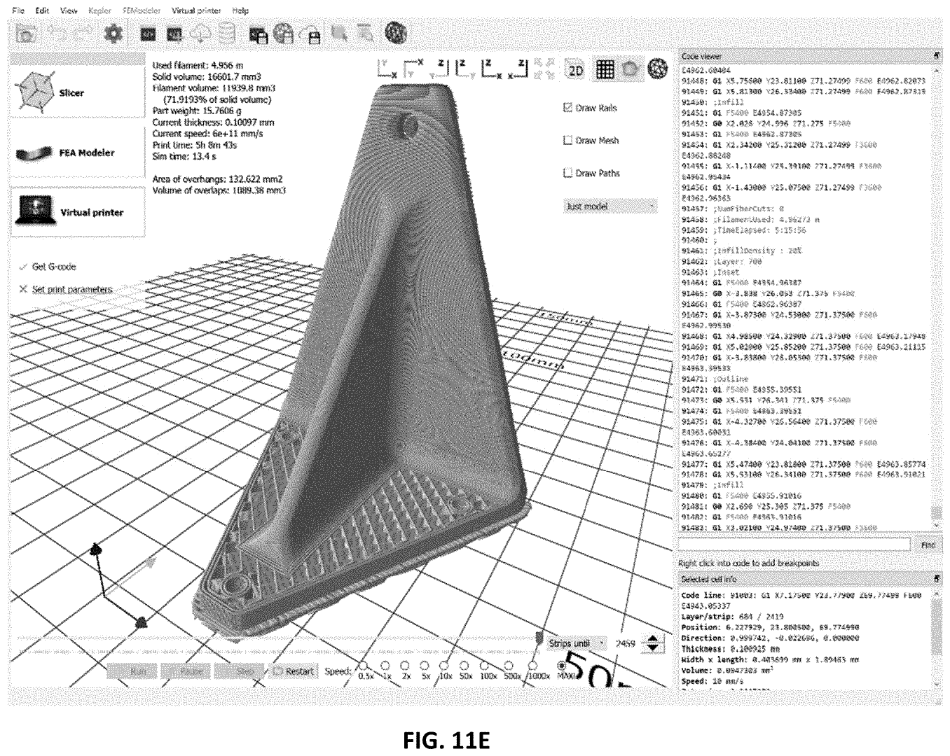

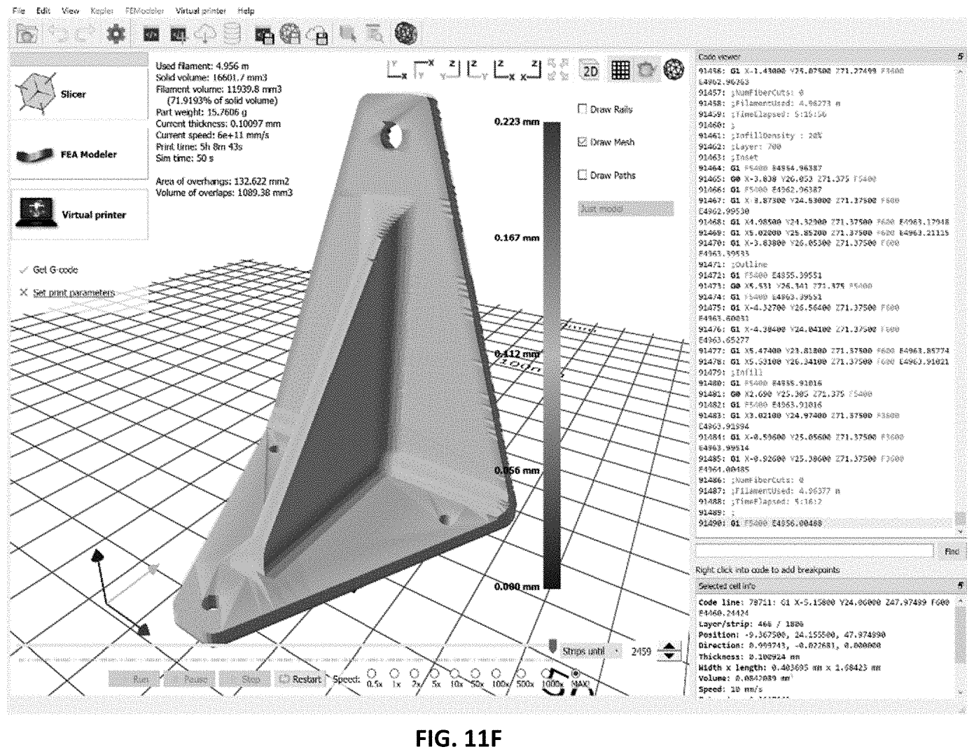

FIGS. 11A-11F show an example of an object going through the process flow 100 in FIG. 1 with the following steps:

An STL model is the sole external input to the process flow 100. Upon loading as shown in FIG. 11A, it is possible to reposition or rotate the object, if desired.

The next operation is FEA analysis. A volumetric mesh, is generated from the surface mesh so it can be simulated using FEA. Boundary conditions and loads that the object is expected to withstand are added to the volumetric mesh, as shown in FIG. 11B. The system is solved using FEA and loads are visualized on the model, as shown in FIG. 11C. This process can be repeated with different materials or load scenarios until the result is satisfactory.

Other post-processing options can allow for direct factors-of-safety examination using different composite failure criteria and plot a variety of stress related metrics.

The toolpath generator then takes the results of the FEA analysis (e.g., stress vectors) and generates toolpaths based on the expected loads, as shown in FIG. 11D. The toolpath generator itself has many settings that can be modified (e.g., perimeters, travel speed, supports). The settings can be saved as a user profile and be used again on subsequent parts.

With the generated toolpath, FEA is re-run to obtain more precise structural strength results that take into account the toolpath orientations. If the results are not satisfactory, the tool path generation can be reviewed and modified.

The toolpath is converted into machine code and simulated in the virtual printer, as shown in FIG. 11E. A user examines and verifies that the toolpath will not cause any issues during the printing (e.g. overlaps or collisions of the object with the tool) and also observe a preview of the finished model. The degree of deviation between the simulated model from the machine code and the original STL mesh can be determined using mesh comparison.

At any point, it is possible to return and repeat the steps until the product is satisfactory.

The steps/operations described above require less than 10 minutes to complete by a reasonably adept AM process engineer. In some cases, the required time for the steps/operations above is greater than at least about 1, 2, 3, 4, 5, 6, 7, 8, 9, 10, 15, 20, 30, 40, 50 minutes, or more. In other cases, the required time is at most about 50, 40, 30, 20, 15, 10, 9, 8, 7, 6, 5, 4, 3, 2, 1 minutes or less. The process resulted in machine code that was verified and finalized for the physical 3D printer without the need to use other software packages. The user was able to use the software immediately and ensure that the generated machine code was of appropriate quality and the 3D object would withstand the AM process without any obstacles.

While preferred embodiments of the present invention have been shown and described herein, it will be obvious to those skilled in the art that such embodiments are provided by way of example only. It is not intended that the invention be limited by the specific examples provided within the specification. While the invention has been described with reference to the aforementioned specification, the descriptions and illustrations of the embodiments herein are not meant to be construed in a limiting sense. Numerous variations, changes, and substitutions will now occur to those skilled in the art without departing from the invention. Furthermore, it shall be understood that all aspects of the invention are not limited to the specific depictions, configurations or relative proportions set forth herein which depend upon a variety of conditions and variables. It should be understood that various alternatives to the embodiments of the invention described herein may be employed in practicing the invention. It is therefore contemplated that the invention shall also cover any such alternatives, modifications, variations or equivalents. It is intended that the following claims define the scope of the invention and that methods and structures within the scope of these claims and their equivalents be covered thereby.

1-43. (canceled)

44. A method for printing a three-dimensional (3D) object, comprising:
(a) processing a computer model of said 3D object to generate a strength or stress profile of said computer model;
(b) using at least (i) said strength or stress profile from (a) and (ii) a topology of said 3D object to generate a tool path for printing said 3D object;
(c) simulating printing of said 3D object using said tool path to yield a simulated 3D object;
(d) analyzing said simulated 3D object to determine whether said simulated 3D object meets a threshold; and
(e) if said simulated 3D object meets said threshold, generating printing instructions comprising said tool path for use by a 3D printer to print said 3D object.

45. The method of claim 44, wherein (a) comprising using finite element analysis (FEA) to generate said strength or stress profile.

46. The method of claim 44, further comprising, subsequent to (a) and prior to (b), using said computer model and said strength or stress profile to obtain said topology of said 3D object.

47. The method of claim 46, wherein obtaining said topology comprises performing topology optimization.

48. The method of claim 46, wherein said topology is optimized by using a solid isotropic material with penalization algorithm.

49. The method of claim 46, wherein said topology is obtained on an isotropic or anisotropic 3D object corresponding to said 3D object from said computer model.

50. The method of claim 46, wherein said topology comprises solid and void regions.

51. The method of claim 44, wherein said topology comprises regions of various densities.

52. The method of claim 44, wherein (b) comprises: (1) generating an initial tool path; and (2) adjusting said initial tool path based on geometric parameters and/or fiber orientation to yield said 3D printer tool path.

53. The method of claim 52, wherein said geometric parameters comprise one or more of: a raster angle of a layer, an infill density, a layer orientation, a perimeter thickness, and a thickness of layer.

54. The method of claim 52, wherein (2) comprises (i) using additive finite element analysis or (ii) adjusting strain-energy density across a plurality of regions of said 3D object.

55. The method of claim 54, further comprising adjusting said strain-energy density across a plurality of regions until a stopping criterion is met, to yield substantial uniformity in said strain-energy density across said plurality of regions.

56. The method of claim 52, wherein (b) further comprises optimizing fiber orientation based on said strength or stress profile, said topology, and/or geometric parameters to generate an optimized fiber orientation.

57. The method of claim 56, wherein (2) is further based on said optimized fiber orientation.

58. The method of claim 44, wherein said threshold is a quality threshold.

59. The method of claim 44, wherein said strength or stress profile comprises information based on estimated or predicted stress, predetermined or calculated material strength, or both.

60. The method of claim 44, wherein said printing instructions comprises machine code to drive said 3D printer based on said tool path.

61. The method of claim 44, wherein two or more among (a)-(e) are performed automatically without involvement of a user.

62. The method of claim 44, wherein (a) further comprising processing design specifications of said 3D object, said design specifications comprising a load and/or a boundary condition.

63. The method of claim 44, wherein (a) comprises generating a 3D orthotropic stress-strain matrix for a plurality of elements of said 3D object.
